(19) United States
(12) Patent Application Publication
(10) Pub. No.: US 2011/0207323 A1
(43) Pub. Date: Aug. 25, 2011

(54) Method of forming and patterning conformal insulation layer in vias and etched structures

(76) Inventor: Robert Ditizio, Petaluma, CA (US)

(21) Appl. No.: 12/712,339

(22) Filed: Feb. 25, 2010

(51) Int. Cl. H01L 21/768; H01L 21/311

(52) U.S. Cl. 438/675; 438/696; 257/E21.249; 257/E21.597

(57) ABSTRACT

Vias are formed in a substrate using an etch process that forms an undercut profile below the mask layer. The vias are coated with a conformal insulating layer and an etch process is applied to the structures to remove the insulating layer from horizontal surfaces while leaving the insulating layers on the vertical sidewalls of the vias. The top regions of the vias are protected during the etchback process by the undercut hardmask.

This invention relates to a method and apparatus for providing conformal electrical isolation in vias and other patterned structures in microelectronic, nanoelectronic, Micro-electromechanical Systems (MEMS), nano-electromechanical systems (NEMS), optical devices, and other types of devices.

### BACKGROUND OF THE INVENTION

Interest in combining multiple discrete electronic devices within a single package have led to the development of new methods for providing electrical contacts through device substrates to allow for three-dimensional (3D) stacking and interconnecting of these devices. Unlike multi-chip modules in which devices are placed side-by-side, and in which interconnects are formed using conventional wire bonding techniques between top surface contacts, through substrate vias allow for 3D stacking of discrete devices in which electrical contacts between the devices are formed through the substrate. A microprocessor and a memory chip could be combined within a single package, for example, to reduce the space occupied by the two discrete components. Stacked configurations allow for improved signal transmission between two or more interconnected devices, and correspondingly reduced power consumption, relative to the side-by-side, or laterally packaged devices that are interconnected using wire-bonding or other lateral interconnection scheme. Additionally, 3D packaging of multiple devices provides for reduced chip packages in comparison to laterally packaged devices and to the use of multiple discrete devices, an important consideration for mobile phones, netbooks, and other portable electronic devices that require compact product size and long battery life.

System in Package (SiP) architectures in which multiple chips are stacked together have led to the development of processing strategies for creating interconnects from the front side of a substrate to the backside. Part of the manufacturing integration strategy is the development of processes for creating vias through the individual device substrates, and in interposers that are used as intermediate layers between devices. The primary purpose of the vias is to allow for the formation of arrays of conductive plugs to carry electrical signals between the stacked chips. The current-carrying conductive plugs must be insulated from the substrate in structures that utilize conductive substrate materials such as silicon, the most widely used substrate material in the manufacturing of electronic devices.

### SUMMARY

The present invention addresses a need in the art for the formation of conformal insulation layers, on the sidewalls of etched structures, with high throughput. In an embodiment, the present invention allows for the utilization of cyclic etch processes that provide high etch rates and scalloped sidewalls. In the current state of the art, cyclic and non-cyclic processes are utilized that minimize sidewall roughness, or scalloping, to compensate for inadequate coverage of subsequently deposited insulation layers. Etch processes that are developed to provide minimal sidewall roughness are typically slow, with correspondingly slow throughput. In an embodiment, the current invention utilizes etch processes that are characterized by high etch rates and correspondingly high production throughputs. Additionally, current methods in the art use insulating layers that have low conformality, for which the formation of a continuous, uniform sidewall coating is difficult. In an embodiment, the current invention utilizes polymeric films that produce continuous films of uniform thickness and these coatings can be produced in high aspect ratio vias and etch structures that cannot be uniformly coated with current insulator deposition technology.

In addition to the use of high throughput etch processes and highly conformal films, the etched structures in embodiments of the current invention provide for the formation of an overhang that enables the same mask pattern that was utilized to produce the via or etched structure to be used to protect areas of the structure that would be sensitive to degradation in the absence of the overhang and also provides for the removal of the conformally deposited insulator layer from areas of the structure where they are not required for subsequent processing.

In an embodiment, the inventive process provides a method of forming insulating layers on sidewalls of structures used in the fabrication of semiconductor devices. In an exemplary process, a method is provided for creating a pre-formed overhang in a structure with a mask, for depositing a conformal film over and below the mask and within the structure, and an etch process for removing the conformal films from areas in which the film is not required for subsequent processing, or is not required in the device structure of some devices. Similar approaches are not available with the two most common insulators in use in semiconductor device fabrication, namely silicon dioxide and silicon nitride, because of the poor conformality of the film coverage with these films and the lack of processes for selective removal of these materials from complex three dimensional structures.

In an embodiment, the current invention provides a method for producing conformally deposited insulating layers on etched sidewalls for which the constraints of producing low roughness on the sidewall of the vias during the etching of the vias is greatly reduced or eliminated. Currently used methods such as silicon oxide layers, for example, closely follow contours in the sidewall that are created during the etching of vias in silicon. The use of parylene coatings, and other materials that can be deposited in a highly conformal manner, tend to smooth the roughness produced by typical etch processes and allow for very aggressive etch conditions to be utilized to provide reduced processing costs relative to insulating materials that do not possess the same tendency to smooth sidewall roughness as conformal films. Typical silicon etch rates can exceed 20 um/min for processes that yield rough sidewalls in contrast to <5 um/min for processes that yield smooth sidewalls. In an embodiment, the inventive process allows for, although is not limited to, the use of the higher etch rate processes to maximize throughput and reduce manufacturing costs in process flows that utilize the inventive process.

The flexibility for using high etch rate processes in embodiments of the inventive process, provides for the introduction of a means for mechanically anchoring insulating layers to substrate sidewalls, and conductive films and plugs to the insulating layers to overcome limitations that might exist from the effects of differences in the coefficients of expansion of materials, for poor adhesion between films in structures that are fabricated using the inventive technique, and for changes in film properties that might result from device fabrication steps that follow the inventive process.

In the current state of the art, aside from efforts to minimize sidewall roughness during the etch to minimize the formation of roughness in the subsequently formed insulation layer, precautions are generally taken to minimize undercut of the mask layer, also resulting in increased processing costs. Processes that produce little or no undercut are typically slower and, therefore, more costly.

Undercutting of the mask typically complicates the implementation of silicon oxide coatings due to the lower observed conformality of these coatings and the inability to coat cavities or undercut structures with the methods commonly used to deposit these films. In embodiments of the present invention, controlled undercutting of the mask is a key element of this inventive process. Aggressive etch steps can be utilized that produce high etch rates to minimize overall processing time and conformal films are utilized that can easily fill cavities and undercut structures that are required in the inventive process. The intentional undercut of the mask layer produces a favorable and necessary geometry that allows for removal of the conformal film, and in particular parylene, from areas outside of the etched structure 40 at the top and edges of mask 30 without the need for a remasking step. During the etchback step 150 in which the conformal film is removed from areas in which this film is not required for subsequent processing, the undercut of the mask protects the interface between the insulating layer and the substrate in a way that is not available with current processing methodologies.

In an embodiment, the re-use of the mask layer 30 to protect the insulating sidewall layer 20 with the same mask that is used initially to define the etch structure 40 during the substrate etch process is beneficial in reducing the number of steps in the fabrication process and in reducing manufacturing costs. Mask layer 30 is used to protect the insulating sidewall 20 on sidewall 50 while allowing for the removal of the insulating layer 20 from the top of mask layer 30, from the areas within the mask opening at the top of the features 40, and in some embodiments from the horizontal surface 52 at the bottom of etch structure 40 in areas where it is not required for subsequent processing.

In an embodiment, the mask layer 30 does not require removal after etchback step 150. The mask layer 30 can be used as an integral insulating layer with insulator layer 20 in completed devices. This additional re-use further reduces manufacturing costs.

### BRIEF DESCRIPTION OF THE DRAWINGS

FIG. 1. Embodiment of the inventive process showing cross sectional view after 1a) providing a patterned structure, 1b) conformal film deposition, and 1c) etchback of conformal coating.

FIG. 2. Process sequence of the inventive process.

FIG. 3. Schematic of parylene deposition module.

FIG. 4. Cross section of an etched structure in which an embodiment of the inventive process is used to create an insulating sidewall layer.

FIG. 5. Another embodiment of the inventive process.

FIG. 6. Various cross sections of etched via structures applicable to the inventive process.

FIG. 7. Cross section of via structure after conformal insulator deposition step.

FIG. 8. Examples of conformality of insulating layer.

FIG. 9. Via with insulating sidewalls formed using the inventive process.

FIG. 10 A preferred embodiment of the inventive process.

FIG. 11. Examples of anisotropic etch for removing conformal dielectric layer.

FIG. 12. Cross section of an etched structure in which an embodiment of the inventive process is used to create an insulating sidewall layer shown with mechanically anchored insulator layer and fill.

### DETAILED DESCRIPTION OF THE INVENTION

Introduction

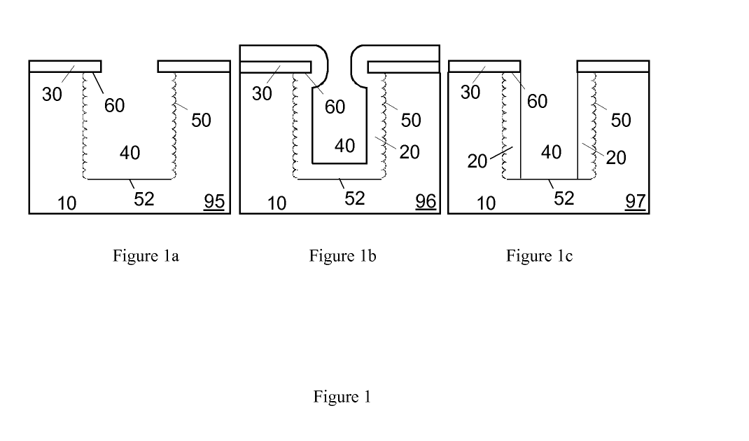

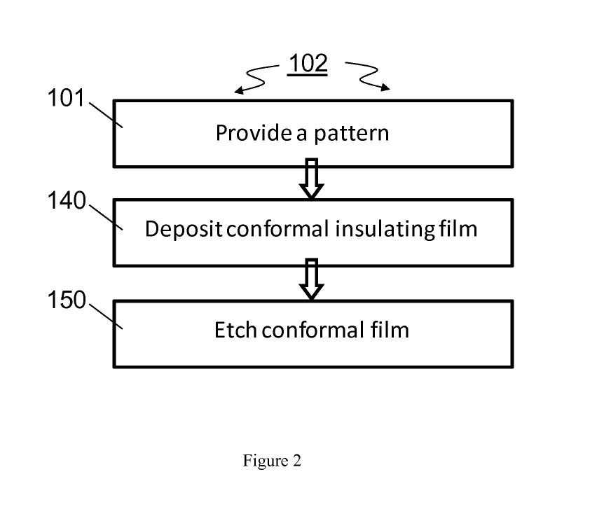

An embodiment 102 of the inventive process is provided in FIG. 1 and FIG. 2. In FIG. 1, the progression of an etched structure through the steps in the inventive process is shown. The corresponding process flow for the steps shown in FIG. 1 is shown in FIG. 2.

In an embodiment 102 of the current invention, a patterned substrate 95 with at least one etched structure is provided 101 as shown in FIG. 1a. In the preferred embodiment, substrate 95 contains at least one patterned structure 40 with overhang 60 from mask layer 30. In the preferred embodiments, mask layer 30 is silicon oxide or silicon nitride. In the preferred embodiment, the patterned substrate 95 is a through-substrate-via or a through-silicon-via (TSV). One common method for forming TSVs utilizes a cyclic etch process in which holes are formed in silicon substrates with a process of alternating etch and deposition steps. Initially, silicon is removed through a patterned masking layer that is formed on the top surface of the substrate. Etching proceeds through the silicon using an etch gas such as sulfur hexafluoride (SF₆) to isotropically remove exposed silicon for a short period, typically 2-10 seconds, followed by a passivation step in which a fluorocarbon-containing gas such as C₄F₈ is used to deposit a thin layer on the sidewalls of the etched silicon to prevent lateral etching in subsequent cycles. In the second and subsequent cycles, the SF₆ etch step must remove the thin fluorocarbon layer from the horizontal surface at the bottom of evolving vias, and other etched structures, as well as a targeted thickness of silicon as determined by the allowable lateral etching of the silicon for the targeted application. In an isotropic etch process, the vertical and lateral etch depths are roughly equivalent, and therefore, as the duration of the SF₆ etch step in the cyclic process is increased, the corresponding lateral and vertical etch depths in the silicon are also increased. The lateral etch depth in each cycle will effect the degree of roughness, commonly referred to as scalloping, produced in the sidewall of the evolving vias, and other patterned structures, during the SF₆ etch steps.

In the preferred embodiment, a conformal insulation layer is deposited 140 onto the patterned substrate 95 as shown in FIG. 1b to provide a coating over the exposed surfaces of mask layer 30 and etch structure 40 to produce structure 96. In the preferred embodiment, the conformal coating 20 is parylene, and the coating is applied over the scalloped sidewalls 50 in the etched structures 40. Parylene is the trade name for a variety of deposited poly(p-xylylene) polymers.

The scalloped sidewalls in silicon vias, trenches, and other patterned structures can be difficult to coat with conformal low temperature silicon oxide, a commonly used insulating material in integrated circuit manufacturing. Deep vias, such as those used in the formation of through-substrate-vias, can have aspect ratios in excess of 10:1 (where aspect ratio is defined as the ratio of via depth to via width). For aspect ratios as low as 1:1, significant differences in film coverage between the top and bottom of etched structures, such as vias, have been observed for plasma enhanced chemical vapor deposited (PECVD) silicon oxide layers. The observed differences in film thickness between the top and bottom of the vias greatly influence the effectiveness of subsequent steps in the device fabrication process that follow the deposition of the insulation layer on the sidewall of the vias. If, for example, the insulating film thickness at the top of a via is 2-3 times as thick as at the bottom of the via, the encroachment of the thicker oxide into the opening at the top of narrow vias, can shadow the sidewalls at the bottom of the via from incoming deposition materials making it difficult to form a continuous insulating layer at the bottom of the via.

Therefore, there is a need in the art for a method of forming insulating layers on sidewalls of structures used in the fabrication of semiconductor devices that is not hampered by the buildup of excess deposition material or for processes that can accommodate this buildup. In the inventive process, a method is provided for creating a pre-formed overhang in a structure with a mask, for depositing a conformal film over and below the mask and within the structure, and an etch process for removing the conformal films from areas in which the film is not required for subsequent processing. Similar approaches are not available with the two most common insulators in use in semiconductor device fabrication, namely silicon dioxide and silicon nitride, because of the poor conformality of the film coverage with these films and the lack of processes for selective removal of these materials from complex three dimensional structures.

Suitable insulating films for coating vias, in general, have a high dielectric breakdown voltage and are deposited as continuous, pinhole-free layers with uniform thickness and uniform film properties. In many applications, it is favorable, but not necessarily required, to have the insulating film thickness at the top of the via or etched structure 40 approximately equal to the insulating film thickness at the bottom of the via or etched structure 40. Films deposited on the horizontal surfaces 52 at the bottom of vias are typically removed at some point in the process flow. The ability to control the smoothness at the surface of the deposited insulating film is also an important characteristic of the insulating materials used in TSV applications. Rough sidewall surfaces can lead to wide variations in the film thickness of insulating layers that are deposited over rough sidewall surface morphologies. Conformally deposited films have a tendency to smooth rough surfaces rather than to accentuate surface roughness. The conformality of a deposited film is generally linked to the sticking coefficient of the molecular species that are delivered to the substrate in chemical vapor deposition processes. The sticking coefficient has a value between 0 and 1 and its value for a particular material and process is, to some extent, a measure of the probability that impinging gas molecules will adhere to the surface of the growing film. The sticking coefficient can be affected by processing equipment configurations and process conditions such as substrate temperature, for example. If the sticking coefficient is low, or close to 0, the deposited films tend to be conformal. Conversely, if the sticking coefficient is high, or close to 1, then the conformality of the growing film is generally quite low. Poor conformality generally leads to poor step coverage in TSV structures.

Parylene

Parylene is formed from the precursor, [2.2]paracyclophane dimer, that is typically produced in powder form. In its unsubstituted molecular form, typically known as parylene-N, the material is also known as di-para-xylylene. The molecular structure of the parylene-N dimer consists of two benzene rings that are joined via carbon bridges attached at the para positions. Other variants of parylene have also been derived, such as parylene-C and parylene-D in which chlorine is present in the molecular structure. Parylene-C, for example, contains a chlorine atom that is attached to each benzene ring and Parylene-D contains two chlorine atoms per ring. A number of fluorinated parylenes have been produced as well. The presence of the additional elements in the molecular structure of parylene monomers generally affects the properties of parylene films. Films that are fabricated from fluorinated parylenes, for example, have a greater tolerance for high temperature applications than non-fluorinated parylene films.

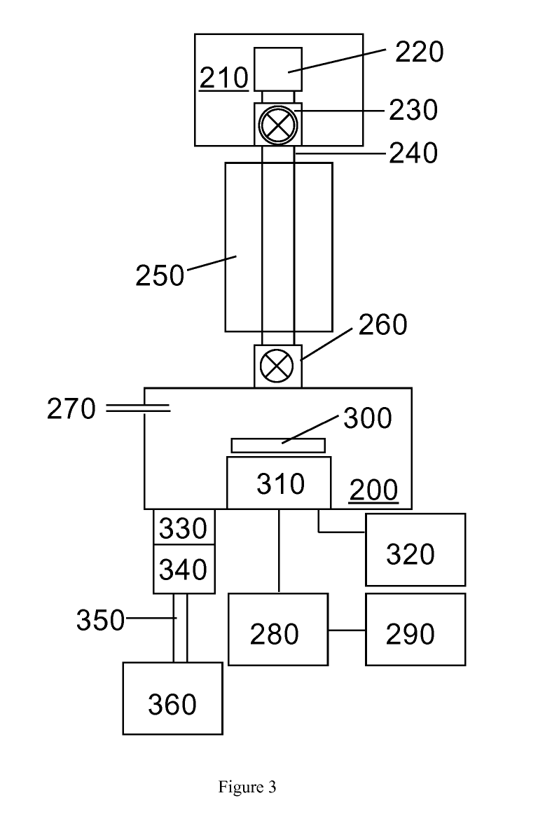

Deposition of parylene thin films is generally achieved by the application of a heat source to the [2.2]paracyclophane dimer to produce an ambient temperature in the range of 160-180° C. to form a vapor, which is then passed through a cracking furnace at temperatures in the range of 550-750° C. to split the dimer molecule into monomer form. The monomer is directed from the cracking furnace to a substrate that is typically at room temperature or below. The deposition rate for parylene is inversely proportional to substrate temperature. Typical substrate temperatures are in the range of −40 to +30° C. although lower temperatures can be used. Increasing deposition rates are attainable at temperatures below −40° C. and can in principal be utilized to produce higher deposition rates than that available at higher temperatures although the cost of the hardware and the operating costs required to produce the lower temperatures typically increases as well. Deposition temperatures as low as liquid nitrogen temperatures (77K) have been reported. As the monomer vapor reaches the cooled substrate from the cracking furnace, it condenses onto the wafer and self-assembles into a long-chain polymer. The entire process is performed at low pressure in a vacuum. Typical pressures in the parylene deposition chamber are in the range of 10-200 mTorr. A schematic showing typical components in a parylene deposition system is shown in FIG. 3.

FIG. 3 shows a schematic of a process module that can be used to deposit conformal parylene layer 140 and to provide an in-situ etchback 150 in the preferred embodiment. In this preferred embodiment, parylene is used as the insulation layer 20 deposited in insulator deposition step 140, and an in-situ etchback step 150 is used to remove the insulation layer 20 from areas in which the insulation layer is not needed or desired.

In the preferred embodiment of the inventive process shown in FIG. 2, the insulating layer 20 is parylene and is deposited using a process module such as the one shown schematically in FIG. 3. FIG. 3 shows a parylene deposition system with dimer vaporizing oven 210 with dimer ampoule 220 connected to furnace tube 240 and cracking furnace 250 through throttle valve 230. In operation, dimer ampoule 220 is heated in dimer oven 210 to a temperature typically in the range of 160 to 180° C. to form dimer vapor, which is then transported through valve 230 to regulate the flow of dimer, into cracking furnace 250. The dimer cracking furnace 250 is typically operated at a temperature in the range of 550 to 750° C. to split the dimer molecules into monomer molecules of parylene vapor, the precursors for the deposited film. From the cracking furnace 250, the monomeric parylene enters the process chamber, typically, but not necessarily, through a set of one or more isolation valves 260 to the process module 200. Substrate 300 is placed on electrode 310 which is cooled to typical temperatures in the range of −40 to +30° C. with temperature control unit 320. Electrode 310 is preferably, but not necessarily, an electrode with electrostatic or mechanical clamping and the capability to provide gaseous backside cooling of the substrate with helium, nitrogen, or argon for improved control of the temperature of substrate 300. For application of the parylene films to semiconductor and MEMS wafers under vacuum, for example, the wafer can be clamped using an electrostatic or mechanical clamp to maintain the desired wafer temperature, particularly at temperatures below ambient conditions. Backside thermal transport gas can also be used to cool the wafer and to allow for more precise control of the wafer temperature. In practice, low temperatures provide the means for producing high deposition rates and high throughput.

Parylene deposition processes can easily exceed 0.5 microns/minute, comparable to typical PECVD oxide processes.

Other process module configurations can be used with embodiments of the inventive process to deposit parylene insulator 20 and to produce etch 150 of the parylene 20 after the deposition process 140 and remain within the scope of the present invention. Parylene deposition equipment such as those produced by Specialty Coating Systems of Indianapolis, Ind. can also be used, for example, to provide the insulator 20. Single wafer process modules such as the module shown in FIG. 3 provide improved process repeatability and control over batch systems such as those produced by Specialty Coating Systems. Additionally, single wafer configurations such as the configuration shown in FIG. 3 can eliminate undesired coating of the backside of substrates 300. Single wafer tools can be configured with endpoint systems that are connected to the process module through an automated control system to trigger the end of the deposition step allowing for improved process repeatability. Single wafer processing tools can also provide faster deposition rates and more uniform film properties than batch systems due to the ability to provide cooling of the substrate and the ability to provide improved control of the uniformity of the temperature of the substrate 300 during parylene deposition.

In the preferred embodiment, the step 140 for depositing the conformal insulating layer 20 is followed by an etchback step 150 in which the conformal film 20 is removed from areas of the substrate 300, as shown in FIG. 1c, that have a line of sight to the plasma used in etchback step 150. In this preferred embodiment, the etchback step 150 is an anisotropic etch process in an oxygen-containing plasma to remove conformal parylene layer 20 from areas of the substrate 96 in which the coating is not required to produce substrate 97. The use of the anisotropic etch process 150 preferably restricts the removal of the conformal parylene coating 20 to surfaces that have a direct vertical line of sight, or nearly direct vertical line of sight to the opening in mask layer 30 as shown in FIG. 1c. No re-masking of the structure is required since the oxygen process is highly selective to the removal of the conformal polymeric film 20 relative to hard mask materials such as silicon oxide and silicon nitride.

Although not required, an embodiment of the inventive process allows for keeping the mask layer 30 in place after the process as an integral part of the structure.

FIG. 1c shows substrate 97 in which the conformal insulating layer 20 has been removed from the upper surface of mask layer 30, from the edge of the opening in mask layer 30, and from the bottom of the etch structure 40. Some incidental or intentional removal of material from the exposed surface of conformal insulating layer 20 might also occur depending on the lateral excursion of overhang 60 into etch structure 40 relative to the thickness of the conformal insulating film 20. In an embodiment in which the conformal film 20 on the sidewall is thicker than the overhang 60 is wide, some removal of the conformal layer 20 is to be expected. In an embodiment in which the conformal film 20 is thinner than the overhang 60 is wide, then minimal or no removal of the conformal film 20 is expected.

In embodiments in which conformal insulating layers 20 are too thin to smooth the scalloping or roughness on sidewall 50, the etchback step 150 could produce some intentional or unintentional smoothing of the conformal coating 20. This is particularly true in embodiments in which the width of the overhang 60 is approximately equal to the thickness of the conformal coating 20 so as to expose the conformal coating 20 to the anisotropic etch step 150.

The use of roughened sidewalls, typically an artifact of high throughput silicon etch processes, is encouraged by embodiments of the current invention.

Device Structure with through Substrate Via

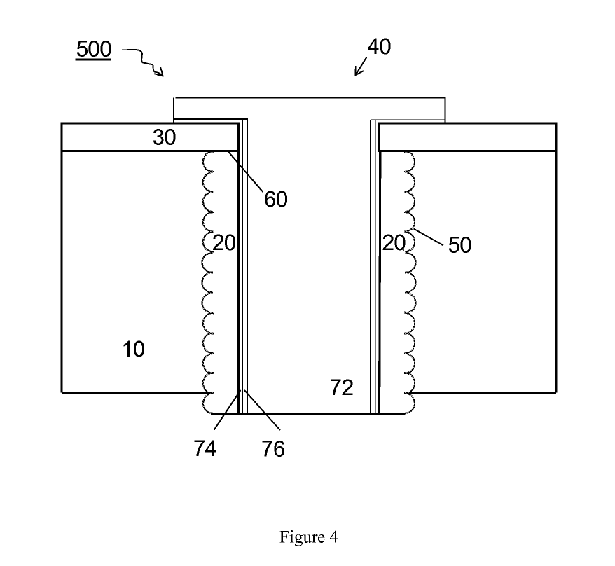

In FIG. 4, a cross-section of a device structure 500 that incorporates the inventive process 102 in the fabrication of a through-substrate-via is shown. Inventive process 102 is well-suited for the fabrication of through silicon vias, but its application is not limited to through silicon vias.

In the example shown in FIG. 4, insulator layer 20 has been deposited over sidewall 50, barrier layer 74 has been deposited over conformal insulator layer 20, and seed layer 76 has been deposited over barrier layer 74. A conductive plug 72 is shown that fills via 40 in substrate 10 to form the conductive pathway through the substrate 10. Device structure 500 also shows that a portion of the substrate 10 has been removed to expose the bottom, as oriented in FIG. 4, of conductive plug 72 and insulator 20.

In the example shown in FIG. 4, an embodiment of the inventive process 102 is shown for which an insulating sidewall is provided on etched structure 40. The inventive process combines the use of conformal coatings with etch processes that provide undercut mask profiles and provide for the removal of the conformal coatings from areas of the device structure in which the coatings are not required for subsequent processing. Mask layer 30 is used for the dual purposes of providing an etch mask for forming the etched structure 40 in substrate 10, and subsequently for removal of the insulating layer 20 from areas of device structure 500 where the insulating layer 20 is not required. The areas from which the insulating layer can be removed in etch step 150, without a requirement to re-pattern, are the areas which have a line-of-sight to an anisotropic plasma. The insulating layer 10 is removed, in whole or in part, from areas of the structure above the plane or planes of the top surface of mask layer 30, from within the patterned opening used to create etched structure 40, and in some embodiments, from the horizontal surface 52 at the bottom of etched structure 40.

Methods in the art for forming conductive plugs 72 through substrates in 3D device stacking applications utilize a combination of integrated process steps in which 1) a substrate such as silicon is exposed to a plasma etch process to create an array of vias, 2) an insulating layer is formed on the sidewalls of the vias, and 3) a conductive material is deposited over the insulating layer within the vias to create a conductive path from the top to the bottom of the via, through the substrate. The conductive material can either completely fill or partially fill the vias to form the conductive path. The insulation layer ideally forms a low capacitance, electrically resistive barrier between the conductive plugs and the substrate to prevent electrical shorting between the conductive plugs and the substrate. An insulating layer that produces a low capacitance between the conductive plug and the substrate is preferred to minimize the attenuation of electrical signals that are transmitted between stacked devices through the conductive plugs. Materials with a low dielectric constant, therefore, are preferred.

Additional process steps are also implemented to prevent unintended and potentially deleterious diffusion of metals across the insulating layer 20 and to facilitate the deposition of conductive materials within the vias. Diffusion barriers 74 consisting of one or more layers of films such as Ti, TiN, Ta, TaN, TiAlN, and NiB, for example, are commonly deposited over the insulating layer 20 to prevent the transfer of metals such as copper from the conductive plug 72 to the substrate. Copper is a commonly used conductive plug material and the diffusion of copper into the silicon can have adverse effects on the performance of electrical devices. Seed layers 76, such as those deposited using physical vapor, atomic layer deposition, nanolayer deposition, electrochemical deposition, and other deposition techniques, are also used to initiate electrochemical deposition of conductive plug materials. The seed layers 76 may or may not be of the same material as the plug material. In some approaches, such as electroless deposition, a seed layer may not be required.

The most commonly used substrate material in use today in the fabrication of electrical devices is silicon. In cases in which silicon is used as the substrate material, the vias are commonly referred to as Through Silicon Vias (TSVs). These vias may extend completely through the silicon substrate during the fabrication process although the more common approach is to stop the etch short of the bottom of the substrate and then to remove the remaining silicon below the vias to form the contacts to the conductive plugs in subsequent process integration steps as shown in FIG. 4.

The substrate 10 can comprise at least one of a single material, a stack of materials, or a stack of device structures. In one embodiment, the substrate 10 can be an insulating substrate in which a thinned layer of silicon or other semiconductor material is attached to an insulating substrate such as glass. In another embodiment, the substrate could comprise a single layer, or multiple layers, of semiconducting, insulating, and metal films. In yet another embodiment, the substrate is an electronic, micro-electromechanical device, or other device in combination with a semiconductor, insulator, or conductive layer or substrate. In yet another embodiment, the substrate is a combination of multiple discrete devices. In yet another embodiment, the substrate is a structure containing at least one of a capacitor, inductor, resistor, transistor, microelectromechanical device, nanoelectromechanical device, and an optical device. In yet another embodiment, the substrate is a structure containing at least one of a capacitor, inductor, resistor, transistor, microelectromechanical device, nanoelectromechanical device, and optical device, and at least one of a semiconductor, insulator, or conductive layer. Other materials and combinations of materials can be used for the substrate and remain within the scope of the inventive process.

In the context of the inventive process, a via is an etched structure 40. An etched structure 40 is any hole or cavity formed in a substrate 10. Structures 40 need not be cylindrically-shaped vias. The shape of the etched structures 40 can be cylindrical with circular, oval, square, rectangular, octagonal, hexagonal, trapezoidal, triangular, or any combination of shapes when viewed from above, or in cross section from a geometric plane taken parallel to the surface of the substrate. The shape of the via or etched structure 40 need not be uniform with etch depth but rather can be gradually changing with depth into the substrate 10. The shape of the via or structure 40 need not be the same from the top to the bottom.

Process Flow

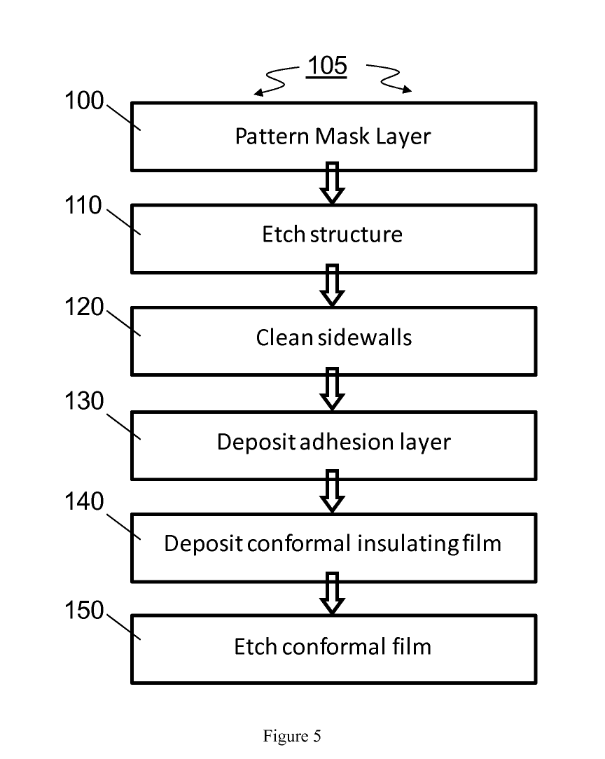

FIG. 5 shows a preferred embodiment of the inventive process with the addition of optional steps, in comparison to the process flow described in FIG. 2, that are typically used in the fabrication of through substrate vias, and in particular, through-silicon vias, among other devices. The inventive process sequence 105 shown in FIG. 5 consists of a number of necessary steps combined with a number of optional steps in the inventive process of forming a conformal insulation layer on the sidewalls of etched features in a substrate.

In mask patterning step 100 in FIG. 5, a patterned mask layer is provided that comprises open areas and masked areas. Masked areas protect the underlying substrate and underlying films below the mask from direct exposure to etch process 110. Conversely, open areas in the mask layer provide access to the underlying substrate and film structure below the mask layer to enable the removal of material in etch process 110. Methods for providing mask layers and patterns are well known in the art and within the scope of the current invention.

In a preferred embodiment, the mask layer is a hard mask and preferably comprised of silicon oxide or silicon nitride. In yet another embodiment, a photoresist mask is used. In yet another embodiment, a combination of a photoresist mask and a hard mask is used to provide the patterned mask layer 30. In yet another embodiment, a metal mask layer is used. In yet another embodiment, a mask structure is used in which a combination of one or more of an insulating layer, a metal layer, and a semiconductor layer are used. In yet another embodiment, the via mask is formed by patterning one or more of the layers of a film structure of a fabricated device that may or may not have been originally intended for use as a mask but that are sufficiently compatible with the inventive process to enable their use as a mask. In yet another embodiment, the via mask is a patterned PR layer over one or more layers of a film structure of a fabricated device. Other embodiments in which a patterned opening is created for the purpose of providing access to an underlying substrate or film structure below at least one mask layer or patterned opening for the purpose of enabling the removal of material from the underlying substrate or film structure, are within the scope of mask patterning step 100.

Cyclic Etching

Step 110 of the inventive process is an etch process step used to create an etched structure in a substrate. In the preferred embodiment, the etched structure is a through-silicon-via. In another embodiment, the etched structure is a through-substrate-via in which the substrate is comprised of at least one layer of silicon and one layer of glass. In yet another embodiment, the etched structure is a through-substrate-via in which the substrate is comprised of at least one layer of semiconductor material and one layer of insulating material. In yet another embodiment, the etched structure is a through-substrate-via and the substrate is comprised of a structure containing at least one of a capacitor, inductor, resistor, transistor, microelectromechanical device, nanoelectromechanical device, optical device, and a BioMEMS device. In yet another embodiment, the etched structure is a through-substrate-via and the substrate is composed of a device structure containing at least one of a capacitor, inductor, resistor, transistor, microelectromechanical device, and a nanoelectromechanical device and a semiconductor layer, an insulating layer, and a metal layer. Step 110 can etch completely through, or partway through, the substrate 10.

In yet another embodiment, the etched structure 40 is a trench formed in a substrate.

In a preferred embodiment, cyclic etch step 110 comprises an SF₆ plasma etch exposure to remove a thin layer of silicon from within etch structure 40 and an exposure to a C₄F₈ plasma deposition step to passivate or coat the sidewalls 50 to prevent, or slow the rate of, lateral etching in subsequent SF₆ etch steps in the cyclic etch process 110.

Lateral etching in silicon occurs because of the isotropic characteristic of the SF₆ etch step. The use of an isotropic etching chemistry such as SF₆ for removing silicon is typical to achieve the highest possible vertical etch rates. Lateral etching is not necessary, or desirable, but rather is a consequence of the high reactivity between fluorine and silicon. In cyclic etch processes comprised of alternating etch and deposition steps, the sidewall at the base of an evolving via is not protected during the incremental SF₆ isotropic etch step and remains exposed until the subsequent exposure to the passivation step in which the sidewall is coated with a thin layer of fluorocarbon products from the C₄F₈ plasma. This fluorocarbon layer protects the sidewall from being etched in subsequent SF₆ etch steps.

The resulting profile from cyclic etch processes in silicon substrates using a combination of SF₆ for the silicon etchant, and C₄F₈ to provide the thin fluorocarbon passivation layer, is a vertical or near-vertical profile with scalloped sidewalls. This technique has been used to etch vias, trenches, and other structures to depths of 100s of microns into the bulk of silicon substrates.

The duration of the isotropic etch step in a cyclic etch process is a significant contributor to the degree of roughness, or scalloping, on the sidewall of etched feature 40. When the duration of the isotropic etch step is short, the corresponding sidewall roughness can be reduced. A duration of 2 seconds during the isotropic SF₆ etch step used in a cyclic etch process to etch silicon, will produce much shallower scalloping than an SF₆ etch step with a duration of 5 seconds, all other conditions being the same. As the duration of the etch step is increased, the extent of the lateral penetration into substrate 10 increases, and the depth of the sidewall roughness in scalloped sidewall 50 also increases. Control of the sidewall roughness, as characterized by the differences between the peaks and valleys in the scalloped sidewall 50, is an important factor to be considered in the integration of cyclic processes, and variations of the cyclic processes, with subsequent steps in which insulating and conductive films are deposited onto the sidewalls of the etched structures 40 and vias 40.

In the preferred embodiment, etch step 110 is a cyclic etch with alternating etch and deposition steps for creating a via structure 40 in silicon

In another embodiment, cyclic etch step 110 comprises an SF₆ plasma etch exposure to remove a thin layer of silicon from within structure 40 and an exposure to a C₄F₈ plasma deposition step to passivate or coat the sidewalls 50 to prevent, or slow the rate of, lateral etching in subsequent SF₆ etch steps in the cyclic etch process 110, and an exposure to an oxygen-containing plasma step to remove the C₄F₈ passivation layer, in whole or in part, from the horizontal surface 52 at the base of the etch structure 40 prior to the subsequent SF₆ plasma etch step in the cyclic process 110.

In yet another embodiment, cyclic etch step 110 comprises an SF₆ plasma etch exposure to remove a thin layer of silicon from within structure 40 and an exposure to a C₄F₈ plasma deposition step to passivate or coat the sidewalls to prevent, or slow the rate of, lateral etching in subsequent SF₆ etch steps in the cyclic etch process 110, and an exposure to a plasma containing SF₆ and oxygen to remove the C₄F₈ passivation layer, in whole or in part, from the horizontal surface 52 at the base of the etch structure 40.

In yet another embodiment, cyclic etch step 110 comprises an SF₆ plasma etch exposure to remove a thin layer of silicon from within structure 40 and an exposure to a C₄F₈ plasma deposition step to passivate or coat the sidewalls 50 to prevent, or slow the rate of, lateral etching in subsequent SF₆ etch steps in the cyclic etch process, and an exposure to a plasma containing SF₆ and oxygen to remove the C₄F₈ passivation layer, in whole or in part, from the horizontal surface 52 at the base of the etch structure 40.

In yet another embodiment, cyclic etch step 110 comprises an SF₆ plasma etch exposure to remove a thin layer of silicon from within structure 40 and an exposure to a C₄F₈ plasma deposition step to passivate or coat the sidewalls 50 to prevent, or slow the rate of, lateral etching in subsequent SF₆ etch steps in the cyclic etch process, and an exposure to a plasma containing C₄F₈ and oxygen to remove the C₄F₈ passivation layer, in whole or in part, from the horizontal surface 52 at the base of the etch structure 40.

In yet another embodiment, cyclic etch step 110 comprises an SF₆ plasma etch exposure to remove a thin layer of silicon from within the etch structure 40 and an exposure to a CHF₃ plasma deposition step to passivate or coat the sidewalls 50 to prevent, or slow the rate of, lateral etching in subsequent SF₆ etch steps in the cyclic etch process 110.

In yet another embodiment, cyclic etch step 110 comprises a plasma etch exposure to remove a thin layer of the substrate from within the etch structure 40 and an exposure to a plasma deposition step to passivate or coat the sidewalls 50 with a fluorocarbon layer to prevent, or slow the rate of, lateral etching in subsequent plasma etch steps in a cyclic etch process 110, and an exposure to a plasma containing oxygen to remove the fluorocarbon passivation layer, in whole or in part, from the horizontal surface 52 at the base of the etch structure 40.

In yet another embodiment, cyclic etch step 110 comprises a plasma etch exposure to remove a thin layer of the substrate from within etch structure 40 and an exposure to a plasma deposition step to passivate or coat the sidewalls 50 to prevent, or slow the rate of, lateral etching in subsequent plasma etch steps in cyclic etch process 110.

An advantage of the embodiments that use the inventive process 102 is the use of processes with high lateral etch rates. The allowance for high vertical and lateral etch rates with the inventive process, enables the use of less costly gases such as CHF3, to passivate the sidewalls in cyclic etch processes, because of the increased tolerance for surface roughness with the conformal deposition step. The inventive process does not require processes that use less costly gases such as CHF3 but provides for their use, and, in some embodiments, for the elimination of passivation step.

In addition to the most commonly used combination of SF₆ and C₄F₈, with and without the incorporation of oxygen, other gas mixtures can also be used to produce etched structures 40 in silicon substrates. CHF₃, for example, can be used as the source of fluorocarbon passivants for the passivation step in place of the more commonly used C₄F₈. Other additives such as SiF₄ and HBr, with and without oxygen, can also provide passivation in cyclic etch processes.

The addition of a short oxygen-containing etch step or the addition of oxygen to an SF₆ etch step can be used to accelerate the removal of the fluorocarbon layer from the horizontal surface at the bottom of the evolving vias. The oxygen can also be added to the fluorocarbon passivation step although in practice it is not as efficient as the alternative approach of having a specific oxygen-containing etch step for removing the fluorocarbon layer at the base of the evolving via or etched structure 40.

The use of oxygen to remove the fluorocarbon passivation layer on the horizontal surfaces at the bottom of evolving etch structures has been found to reduce or eliminate the silicon etch rate dependence on aspect ratio. In general, etch rates decrease with increasing depth into the substrate. In some high aspect ratio structures, the incorporation of oxygen into the cyclic etch process has been shown to significantly increase the achievable etch depth. Without the incorporation of oxygen into a cyclic silicon etch process comprised of alternating etch and fluorocarbon deposition steps, the removal rate of the silicon can drop significantly or the etching can stop at the bottom of high aspect ratio vias, particularly for features with narrow openings (<10 m, for example). With the incorporation of oxygen, the etch depth can be extended deeper into the substrate in high aspect ratio structures for etch processes that utilize fluorocarbon passivation in the deposition step of a cyclic etch process. In a cyclic etch process comprising an SF₆ etch step and a fluorocarbon deposition step, for example, the oxygen containing step typically follows the fluorocarbon deposition step.

In general, the efficacy of the removal of the fluorocarbon passivation layer from the horizontal surfaces at the bottom of evolving vias during the SF₆ etch step in a cyclic etch process can be improved by incorporating oxygen or an oxygen-containing gas species into the plasma during one or more of the steps in a cyclic etch process.

Variations over the duration of the process, in one or more of the process parameters in one or more of the steps in a cyclic etch process using alternating etch and deposition steps, with or without the addition of a specific oxygen-containing fluorocarbon etch steps, can also be used within the scope of the present invention. Specific process parameters that might be systematically or non-systematically varied over the duration of the cyclic etch process include gas flow rates, chamber gas pressure, plasma source power, bias power, cycle time, etch deposition ratio, etch time, and passivant deposition time. The duration of the fluorocarbon etch time might also vary over the duration of the cyclic etch process 110 in embodiments in which a specific oxygen-containing etch steps are incorporated to remove the fluorocarbon passivation layer from horizontal surface 52. In embodiments in which other passivants are used, the duration of the passivant etch might also vary over the duration of the cyclic etch process 110 in embodiments in which specific steps are incorporated to cyclic process 110 to remove the passivation layer from horizontal surface 52.

Many methods for forming etched structures in substrates using cyclic etch processes are known in the art and are within the scope of the current invention.

Non-Cyclic Etching

In yet another embodiment, etch step 110 is a non-cyclic reactive ion etch process. In yet another embodiment, etch step 110 is a non-cyclic reactive ion etch process utilizing a process gas or gas mixture that etches the substrate 10. In yet another embodiment, etch step 110 is a non-cyclic reactive ion etch process utilizing at least one of Cl₂, HBr, SiF₄, SF₆, CF₄, CHF3, C4F8, NF₃, Br₂, F₂, and BCl₃. Additionally, one or more of argon, helium, oxygen, nitrogen, hydrogen, and methane could be added to the process gas. In yet another embodiment, etch step 110 is a non-cyclic reactive ion etch process utilizing at least one of Cl₂, HBr, SiF₄, SF₆, CF₄, NF₃, Br₂, F₂, and BCl₃ for etching silicon. One or more of argon, helium, oxygen, nitrogen, hydrogen, and methane could also be added to this gas mixture.

The deposition rate of sidewall passivation layers in non-cyclic processes can also be increased significantly at lower temperatures. SF₆ can be used in combination with oxygen at cryogenic temperatures to produce etched features 40 with low sidewall roughness without the need for the thick non-volatile passivation layers obtained with larger fluorocarbon molecules such as C₄F₈. Additionally, SiF₄ can be used in combination with SF₆ and oxygen at cryogenic temperatures to improve sidewall passivation, if required.

### Preferred Embodiments of Etched Structures

In yet another embodiment, the etch step 110 is a combination of at least one non-cyclic etch step during which at least a part of structure 40 is etched and a cyclic etch step in which a cyclic process is used to etch at least a part of the structure 40. Combinations of cyclic and non-cyclic processes can be used to produce sidewalls 50 with shaped or sculpted profiles that are particularly favorable to the inventive process 102. An initial, non-cyclic etch step comprising SF₆, or a mixture of SF₆ and oxygen, can be used in an embodiment, for example, to widen the structure 40 adjacent to the opening in mask layer 30 at the top of the structure 40, which could then be followed with a cyclic process comprising an SF6 etch step and a C4F8 deposition step to etch the remainder of the structure 40. Alternatively, the parameters of a cyclic process comprising SF6 etch and C4F8 deposition steps can be varied to provide minimal passivation to produce large scalloping in proximity to the mask layer, and smaller scallops throughout the remainder of the etched structure 40. Other combinations of cyclic and non-cyclic processes can be used to provide etch step 110 and be within the scope of the present invention.

In yet another embodiment for etch step 110, wet chemical etching is used to produce all or part of the etched structure 40 in the substrate. In yet another embodiment, a combination of wet chemical etching and one or more of cyclic and non-cyclic plasma etching is used to produce the undercut in substrate material 10 and the corresponding overhang in the mask layer 30.

In yet another embodiment, the substrate 10 is a combination of one or more of GaAs, SiC, Si, quartz, or glass. In yet another embodiment, etch step 110 is a cyclic, non-cyclic, or combination of a cyclic and non-cyclic etch process used to create an etched structure 40 in the substrate 10.

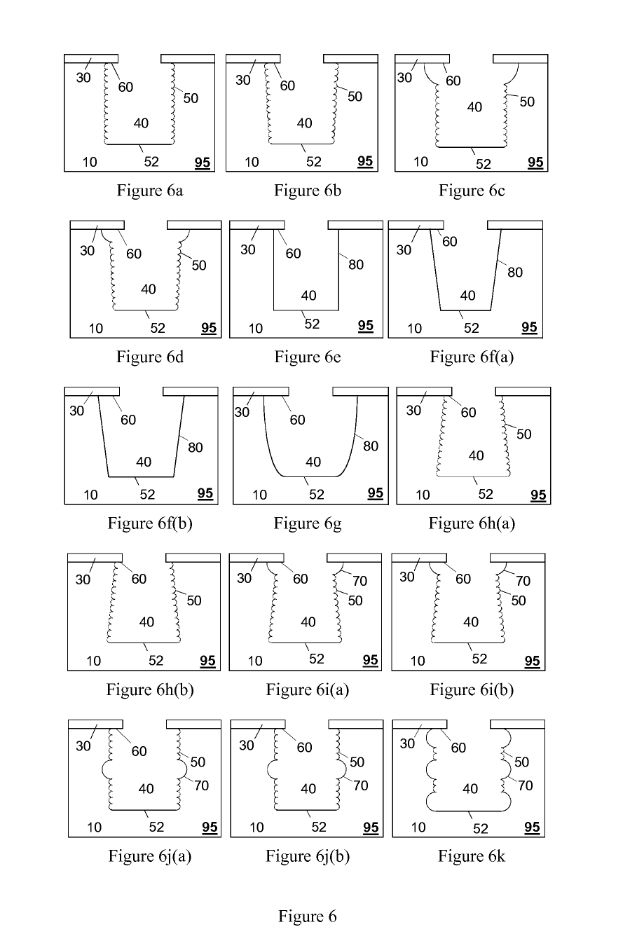

In FIG. 6a to FIG. 6k, examples of etched structures 40 using etch step 110 of the preferred embodiments for the inventive process, are shown.

In FIG. 6a, the structure 40 is shown with scalloped sidewall 50 having a near-vertical sidewall profile in structure 40. The mask structure 30 is shown with overhang 60. The near-vertical sidewall profile with scalloped sidewalls in etched structure 40 shown in FIG. 6a might be produced, for example, with a cyclic etch process.

The etched features 40 in FIG. 6a to FIG. 6k are not necessarily drawn to scale considering that in practice, the depth of feature 40 can be less than the width of feature 40, equal to the width of feature 40, or greater than the width of feature 40. Feature widths in through-silicon-vias, for example, are typically in the range of a few micrometers to fifty micrometers and the depths of these features can extend hundreds of micrometers into the substrate. Other etched features 40 in silicon and other substrates can vary from tens of nanometers to tens of millimeters.

The shape of the via or etched structure 40 need not be uniform with etch depth but rather can be gradually changing with depth into the substrate. The shape of the via or structure need not be the same from the top to the bottom.

In FIG. 6b, structure 40 is shown with scalloped sidewall 50 having a tapered or non-vertical sidewall profile in structure 40. The mask structure 30 is shown with overhang 60. The angled sidewall profile with scalloped sidewalls in etched structure 40 shown in FIG. 6b might be produced, for example, with a cyclic etch process.

In FIG. 6c, structure 40 is shown with scalloped sidewall 50 having a near-vertical sidewall profile for a bottom portion of the sidewall 50, and a large non-vertical scallop 70 at the top of structure 40. The sidewall profile of the structure 40 shown in FIG. 6c with the large scallop 70, might be produced, for example, using an etch process 110 comprising a non-cyclic isotropic etch step for a duration sufficient to form the large scallop 70, and a cyclic etch step to form the near-vertical bottom portion of structure 40 shown in FIG. 6c.

In FIG. 6d, structure 40 is shown with scalloped sidewall 50 having a tapered or angled sidewall profile for a bottom portion of the sidewall 50, and a large scallop 70 at the top of structure 40. The sidewall profile of the structure 40 shown in FIG. 6d with the large scallop 70, might be produced, for example, using an etch process 110 comprising a non-cyclic isotropic etch step for a duration sufficient to form the large scallop 70, and a cyclic etch step to form the tapered or angled bottom portion of structure 40 shown in FIG. 6d.

In FIG. 6e, structure 40 is shown with non-scalloped sidewall 80 having a near-vertical profile. The mask structure 30 is shown with overhang 60. The near-vertical sidewall profile with non-scalloped sidewalls in etched structure 40 shown in FIG. 6e might be produced, for example, with an anisotropic non-cyclic etch process such as SF₆, or a mixture of SF₆ and oxygen. Alternatively, SF₆, or a mixture of SF₆ and oxygen, could be used in combination with low substrate temperatures (<0° C.).

In FIG. 6f(a) and FIG. 6f(b), structures 40 are shown with non-scalloped sidewall 80 having a tapered or angled profile. In FIG. 6f(a), overhang 60 is wider than in FIG. 6f(b) for reasons that will be made apparent. The mask structure 30 is shown with overhang 60. The tapered or angled sidewall profiles with non-scalloped sidewalls 80 in etched structures 40 shown in FIG. 6f(a) and FIG. 6f(b) might be produced, for example, with a non-cyclic etch process.

In FIG. 6g, structure 40 is shown with non-scalloped sidewall 80 having curved sidewalls with curved sidewall profiles. The mask structure 30 is shown with overhang 60. The curved etched profile in FIG. 6g might be produced, for example, with an isotropic, non-cyclic etch process to produce the lateral etch and rounded sidewall.

In FIG. 6h, structure 40 is shown with scalloped sidewall features 50 and a tapered or angled sidewall profile in which the width at the top of the feature 40 is narrower than at the bottom of the etched feature 40. The mask structure 30 is shown with overhang 60. The angled etch profile shown in FIG. 6h might be produced, for example, with a cyclic etch process.

In FIG. 6i, structure 40 is shown with scalloped sidewall 50 having a large scallop 70 at the top portion of structure 40 and a tapered sidewall profile in the bottom portion in which the width at the top of the open feature 40, below large scallop 70, is narrower than at the bottom of the etched feature 40. The mask layer 30 is shown with overhang 60. The etched profile shown in FIG. 6i might be produced, for example, using an etch process 110 comprising at least one non-cyclic isotropic etch step for a duration sufficient to produce the large scallop 70, and at least one cyclic etch step to etch to form the tapered or angled bottom portion of structure 40 shown in FIG. 6i.

In FIG. 6j(a) and FIG. 6j(b), structures 40 are shown with scalloped sidewalls 50 with near-vertical profiles for top and bottom portions of structures 40 and large scallops 70 at an intermediate distance between the top and bottom of structures 40. The mask structure 30 is shown with overhang 60. The etched profiles shown in FIG. 6j(a) and FIG. 6j(b) might be produced, for example, using an etch process 110 comprising at least one cyclic etch step to etch the vertical top portion, one isotropic non-cyclic etch step to form the large scallops 70, and a least one cyclic etch step to etch the vertical bottom portion of structure 40 shown in FIG. 6j(a) and FIG. 6j(b).

In FIG. 6k, structure 40 is shown with scalloped sidewall 50 and large scalloped features 70 at multiple depths in sidewall 50 of etched structure 40. The mask structure 30 is shown with overhang 60. The etched profile shown in FIG. 6k might be produced, for example, using an etch process 110 comprising at least one non-cyclic isotropic etch step to form the large scallop at the top of feature 40, at least one cyclic etch step to form the top near-vertical portion of sidewall 50, at least one non-cyclic isotropic etch step to form the intermediate scallop, at least one cyclic etch step to form the bottom, near-vertical portion of sidewall 50, and at least one non-cyclic isotropic etch step to form the large scallop 70 at the bottom of sidewall 50.

Similar structures with one or more large scallop features 70 can also be produced with tapered sidewalls.

The examples shown in FIG. 6a to FIG. 6k are intended to be representative examples. Additional combinations of etch steps and etch processes can be used to provide the etched structure 40 with overhang 60 below the mask layer 30 and remain within the scope of the inventive process.

Mechanical Anchoring Mechanisms for Insulator to Substrate

Additionally, in the examples shown in FIG. 6a to FIG. 6k, overhang 60 provides a mechanical anchoring mechanism to prevent slippage of the insulating layer 20 relative to the underlying substrate 10. Changes in temperature, for example, might produce conditions that would subject a structure to slippage at the interface of the insulator 20 and substrate 10 or the insulator 20 and the metal layers deposited over insulator layer 20.

Large scallop features 70 shown in FIG. 6c, FIG. 6d, FIG. 6i, FIG. 6j, and FIG. 6k, for example, provide a means for mechanically anchoring the insulating layer to the substrate to prevent slippage at the interface between the substrate 10 and the insulating layer 20 that might occur during temperature cycling after deposition of the insulating layer 20 onto etch structure 40. Temperature cycling can occur, for example, in process steps subsequent to the deposition of the insulator 20, in exposures to a range of ambient conditions during or after fabrication of the device, and in exposures to a range of temperatures produced by the operation of devices in end products.

In FIG. 6c, FIG. 6d, FIG. 6i, and FIG. 6k, large scallop 70 is positioned directly below mask layer 30. The removal of the additional volume of substrate material from substrate 10 in large scallops 70, provides for additional mechanical support when filled with insulator layer 20 in comparison to structures 40 without large scallops. The increased depth of the undercut in the large scallop 70 in these examples also provides for improved electric field breakdown strength at the interface relative to structures without the large scallops 70.

The large scallops 70 in FIG. 6a to FIG. 6k, are shown as having cross sections that are either quarter-circular or semicircular. Other cross sections can also be produced in which an additional volume of substrate material is removed during the etch process step 110 and be within the scope of the present invention.

The depth of the features can be increased or increased significantly relative to the depth shown in FIG. 6a to FIG. 6k to provide additional mechanical anchoring.

FIG. 6i shows a combination of features in etch structure 40 in which yet additional mechanical anchoring between the insulator 20 and the substrate 10 can be achieved. The combination of the large scallop 70 in proximity to the mask layer 30 is combined with a non-vertical sidewall in which the etched width below the large scallop 70 at the top of the feature 40, is less than the etched width at the bottom of the feature 40. The shape of the feature in FIG. 6i provides a structure in which the insulator layer is not free to move in any direction.

Temperature Cycling

Back-end fabrication steps used in the manufacturing of devices often expose device structures to temperatures as high as 450° C., for example, in anneals for alloying metal contacts. Also, chemical vapor deposited barrier layers and seed layers can reach temperatures of 300° C., or higher.

Devices, such as microprocessors, can generate significant amounts of heat during operation in end products that can also expose co-packaged devices to wide ranges of temperature.

These temperature variations can create stresses in structures 96, 97, and in completed device structures that can potentially lead to slippage at the interfaces between the substrate and the insulating layer, and between the insulator and the film or films that cover the insulator layer. The scalloped surface on scalloped sidewall 50 is expected to produce some resistance to slippage in comparison to unscalloped sidewalls, and the incorporation of an adhesion promotion layer can provide additional resistance to movement at the interface. Mechanical anchoring through structural design of the shape of the etched structure 40 as shown in FIG. 6i and through the use of etch features such as large scallops 70, however, provides an additional level of mechanical support. In some embodiments, the redistribution of stress provided by the mechanical anchoring mechanisms in the inventive process can reduce or eliminate the requirements for the scalloping on the sidewalls 50 and on the need for an adhesion promotion deposition step 130.

In applications in which large variations exist in one or more of the temperature coefficients of expansion between the substrate, the insulator, and the metal layers that cover the insulator, a large scallop 70, for example, or a feature shape as provided in FIG. 6i, can provide a means for mechanically anchoring the insulator to the sidewall. The mechanical anchoring produced by scallop 70 can favorably distribute stresses between substrate 10 and insulator 20 within the device structure 40 to eliminate interfacial slippage that might occur in applications in which large variations exist in one or more of the temperature coefficients, and in which the structures are subjected to variations in temperature that would lead to movement at the interfaces.

In addition to differences in the coefficients of expansion between the various materials in the structure 500, for example, other potential reasons exist for providing a means for mechanical anchoring. Poor adhesion between the insulator 20 and substrate 10, for example, can be accommodated with an effective mechanical anchoring mechanism. In some embodiments, the requirement for an adhesion promotion layer can be eliminated with an effective mechanical anchoring scheme. Features such as the large scalloped features 70 can provide a means for mechanically anchoring the insulator to the sidewall that can favorably distribute stresses in applications in which adhesion between the insulator and the underlying substrate sidewall is insufficient to prevent slippage when the structures are exposed to variations in temperature.

Large scalloped features 70 can also provide a means for mechanically anchoring the insulator to the sidewall that can favorably distribute stresses in applications in which the film properties of the conformal insulation layer 20 or a layer that is deposited over layer 20 in subsequent process steps are modified as a result of the exposure to subsequent processing steps, to changes in ambient conditions, or to changes from operation of the devices. These changes might occur as a result of an exposure to a change in temperature, for example. Examples of some film properties that might be changed are density and crystal structure.

The examples of compensating for variations in the temperature coefficients of materials, for poor adhesion, and for changes in film properties are provided for example only. Other reasons might exist for which an embodiment with a means for mechanically anchoring the insulation layer 20 to the substrate 10, in etched features 40, are preferable over other embodiments, and be within the scope of the current invention.

Clean Step

Step 120 of the inventive process in FIG. 5 is an optional step for cleaning the sidewalls of the via after formation of the etch structures 40 in the substrate. In the preferred embodiment, optional cleaning step 120 is an oxygen plasma exposure for removing the fluorocarbon layer from the sidewalls of the vias and trenches after a cyclic etch process containing a fluorocarbon passivation step is used for etching silicon substrate material. In the preferred embodiment, cleaning step 120 is an oxygen plasma exposure performed in-situ in the parylene deposition module prior to the deposition of a parylene insulating layer 140. In another embodiment, cleaning step 120 is performed in a separate module on an integrated processing system on which a parylene deposition module is positioned for depositing the conformal film 20. An integrated process sequence might then allow for the clean step 120 in an oxygen plasma, for example, followed by the deposition of the conformal film in a deposition module on the same equipment. In yet another embodiment, cleaning step 120 is performed in a tool that is separated from the deposition tool.

In other embodiments, cleaning step 120 is at least one exposure of the patterned substrate material to a plasma comprising at least one of an oxygen-containing gas of O₂, CO, CO₂, NO, NO₂, and N₂O, a hydrogen-containing gas of H₂, NH₃, and CH₄, and a fluorine-containing gas of CF₄, SF₆, or NF₃. Nitrogen, argon, and helium might also be used alone or in combination with the at least one of an oxygen-containing gas of O₂, CO, CO₂, NO, NO₂, and N₂O, a hydrogen-containing gas of H₂, NH₃, and CH₄, and a fluorine-containing gas of CF₄, SF₆, or NF₃. The plasma in the embodiments can be generated with capacitively-coupled rf power, inductively coupled rf power, or with microwave power. In another embodiment, cleaning step 120 is an exposure to a source of ozone.

In other embodiments, cleaning step 120 is performed in-situ in the deposition system using at least one of an oxygen-containing gas of O₂, CO, CO₂, NO, NO₂, and N₂O, a hydrogen-containing gas of H₂, NH₃, and CH₄, and a fluorine-containing gas of CF₄, SF₆, or NF₃. Nitrogen, argon, and helium might also be used alone or in combination with the at least one of an oxygen-containing gas of O₂, CO, CO₂, NO, NO₂, and N₂O, a hydrogen-containing gas of H₂, NH₃, and CH₄, and a fluorine-containing gas of CF₄, SF₆, or NF₃.

In other embodiments, cleaning step 120 is performed in a separate module on an integrated processing system on which a deposition module is positioned for depositing a conformal film 20 using at least one of an oxygen-containing gas of O₂, CO, CO₂, NO, NO₂, and N₂O, a hydrogen-containing gas of H₂, NH₃, and CH₄, and a fluorine-containing gas of CF₄, SF₆, or NF₃. Nitrogen, argon, and helium might also be used alone or in combination with the at least one of an oxygen-containing gas of O₂, CO, CO₂, NO, NO₂, and N₂O, a hydrogen-containing gas of H₂, NH₃, and CH₄, and a fluorine-containing gas of CF₄, SF₆, or NF₃.

In other embodiments, cleaning step 120 is performed in a separate tool using at least one of an oxygen-containing gas of O₂, CO, CO₂, NO, NO₂, and N₂O, a hydrogen-containing gas of H₂, NH₃, and CH₄, and a fluorine-containing gas of CF₄, SF₆, or NF₃. Nitrogen, argon, and helium might also be used alone or in combination with the at least one of an oxygen-containing gas of O₂, CO, CO₂, NO, NO₂, and N₂O, a hydrogen-containing gas of H₂, NH₃, and CH₄, and a fluorine-containing gas of CF₄, SF₆, or NF₃.

Methods for cleaning fluorocarbons after dry etching are known in the art and can be used to clean the sidewalls of etched feature 40 after etch step 110 and remain within the scope of the inventive process. Similarly, methods for post etch cleaning after non-fluorocarbon-based chemistries are also well known in the art and can be used to clean the sidewalls of the etched features as remain within the scope of the inventive process.

In yet other embodiments, cleaning step 120 is a wet chemical treatment. In yet another embodiment, cleaning step 120 is an exposure to hydrofluoric acid or a mixture of hydrofluoric acid and water. In yet another embodiment, cleaning step 120 is an exposure to hydrofluoric acid vapor. In yet another embodiment, cleaning step 120 is an exposure to an HF plasma. In yet another embodiment, cleaning step 120 is an exposure to DI water. In another embodiment, cleaning step 120 is an exposure to at least one of hydrofluoric, hydrochloric, nitric, or sulfuric acid, or a cleaning mixture containing one of more of hydrofluoric, hydrochloric, nitric, or sulfuric acid. Many methods for post etch cleaning of etch residues are known in the art and the use of alternative cleaning approaches for optional cleaning step 120 of the inventive process are within the scope of the current invention.

Adhesion Layer Deposition

Step 130 of the inventive process in FIG. 5 is an optional step for depositing adhesion layer 90 for the purpose of improving adhesion between the insulating layer 20 and the substrate 10. In the preferred embodiment, step 130 is a deposition step for applying Silane A-174 (chemical name is [3-(Methacryloyloxy)propyl]trimethoxysilane]) or HMDS (chemical name is Hexamethyldisilazane) to form adhesion layer 90 shown in

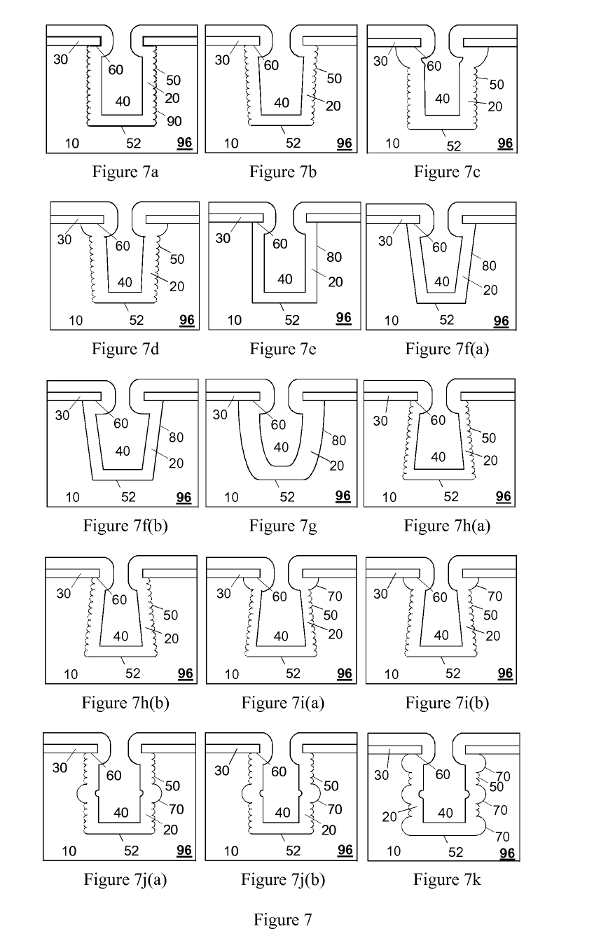

FIG. 7a to improve the adhesion between parylene 20 and silicon substrate 10. In the preferred embodiment, adhesion layer 90 is deposited in a dedicated process module on an integrated processing system in vapor or liquid form. In another embodiment, adhesion layer 90 is deposited in-situ in the deposition module that provides insulating layer 20, prior to the deposition of the insulation layer 20. In yet another embodiment, adhesion layer 90 is deposited in a tool independently of the process equipment used to perform other steps in the inventive process. Processing equipment for depositing HMDS, for example, is present in most semiconductor fabrication facilities and the use of these systems for the deposition of HMDS to provide adhesion layer 90 should be anticipated.

In another embodiment, step 130 of the inventive process in FIG. 5 is an optional step for applying a chemical in vapor or liquid form for the purpose of improving adhesion between the insulating layer 20 and the substrate 10. In yet another embodiment, adhesion layer 90 is a chemical applied in liquid or vapor form in a process module on an integrated processing system. In another embodiment, adhesion layer 90 is deposited in-situ in the deposition module that provides insulating layer 20, in vapor form, prior to the deposition of the insulation layer 20. In yet another embodiment, adhesion layer 90 is deposited in a tool independently of the process equipment used to perform other steps in the inventive process.

In another embodiment, step 130 of the inventive process in FIG. 5 is an optional step for depositing a metal, an insulator, or a semiconductor layer 90 for the purpose of improving adhesion between the insulating layer 20 and the substrate 10.

In yet another embodiment, adhesion layer 90 is a metal, an insulator, or a semiconductor layer deposited in an adhesion layer deposition module on an integrated processing system using adsorptive deposition, physical vapor deposition, chemical vapor deposition, atomic layer deposition, nanolayer deposition, or other deposition method of applying the metal, insulator, or semiconductor.

In another embodiment, adhesion layer 90 is a metal, an insulator, or a semiconductor layer deposited in-situ in the deposition module that provides insulating layer 20, prior to the deposition of the insulation layer 20 using adsorptive deposition, physical vapor deposition, chemical vapor deposition, atomic layer deposition, nanolayer deposition, or other deposition method for applying the metal, insulator, or semiconductor.

In yet another embodiment, adhesion layer 90 is a metal, an insulator, or a semiconductor layer deposited in a tool, independently of the process module used to perform other steps in the inventive process, using adsorptive deposition, physical vapor deposition, chemical vapor deposition, atomic layer deposition, nanolayer deposition, or other deposition method for applying the metal, insulator, or semiconductor. In using atomic layer and nanolayer deposition methods, the deposited material may require treatment steps in addition to the deposition steps to form the required stoichiometric properties of the adhesion layer.

Methods for improving the adhesion between a film and a substrate are known in the art and the use of other methods for optionally depositing an adhesion layer 90 are within the scope of the inventive process.

Conformal Film Deposition

Step 140 of the inventive process is a deposition process used to deposit a conformal insulation layer over some or all exposed surfaces of etch structure 40. In FIG. 7a to FIG. 7k, examples of embodiments after deposition step 140 of the inventive process are shown. In each of the examples shown, the deposited insulating layer forms a continuous coating on the top horizontal surface of mask 30, around and below the opening at the top of the via 40, along the vertical or near vertical scalloped sidewalls to the bottom of the via 40, and on the horizontal surface at the bottom of the via 40.

Conformality

In the preferred embodiment, the conformally deposited insulating layer consists of at least one of parylene-N, parylene-C, parylene D, parylene-HT (manufactured by Specialty Coating Systems), parylene-XiS (manufactured by Kisco), and other forms of parylene, including fluorinated parylene in which the incorporation of fluorine into the parylene occurs in, on, or in proximity to the process module used to perform the deposition.

Another advantage in the use of parylene over PECVD oxide for TSV applications is that the dielectric constant is lower for parylene which results in a lower capacitance to the substrate and less attenuation for signals transmitted between stacked electrical components. Yet another advantage of parylene is the self-planarizing nature of the conformal deposition process. That is, when a film is deposited conformally, the film will tend to fill voids and irregularities in the surface as the thickness of the deposition is increased until the surface becomes smooth. This characteristic is not present in films that do not deposit conformally, such as PECVD silicon oxide.

Yet another advantage in using parylene for TSV applications is that it is typically deposited at temperatures in the range of −40° C. to +30° C. Low temperature processes are generally favorable over high temperature processes particularly for substrates that comprise fabricated devices. Most PECVD silicon oxide processes are performed in the range of 150-400° C. The lower temperature PECVD processes often result in poorer film properties in comparison to the higher temperature processes, particularly along the sidewalls of scalloped trenches and vias. There are many TSV applications in which the maximum permissible deposition temperature is 150° C., and this temperature can be 100° C. for some material structures, or lower. For example, the formation of CMOS imaging sensors often requires pixel-scale micro-lenses that will melt or deform at temperatures above about 150° C. Parylene thin films are also deposited without measureable stress in contrast to PECVD silicon oxides for which the as-deposited stress can be significant.

With a dielectric breakdown strength for parylene at ˜40% of the breakdown strength of deposited silicon oxide, an increase in the minimum film thickness of the parylene is required to achieve the same breakdown strength. For example, with a dielectric breakdown strength of 10 MV/cm for a deposited silicon oxide, a film thickness of ˜14 nm can support up to 10 volts before breakdown failure. The corresponding thickness of parylene required to withstand 10V is ˜36 nm. Although the required thickness is greater for parylene in this comparison to withstand the same voltage, in practice, the non-conformal deposition behavior of the oxide deposition process, used in this example, will require ˜5 times the thickness at the top of the structure 40, or 70 nm, in order to provide the minimum required film thickness at the bottom of the via if deposited with a conformality of 20%. (In this example, a film with a conformality of 20% is defined as a film having a minimum thickness that is 20% of the maximum thickness observed within the same etched structure. In this particular example, the minimum thickness is observed on the vertical sidewall in close proximity to the bottom of the etched structure.) Conversely, the difference in dielectric strength between silicon oxide and parylene requires an increase in parylene thickness of only 2.5 times, or 35 nm, to produce the same breakdown strength. For vias and trenches with high aspect ratios of greater than 1:1, or possibly 2:1, increases in the thickness of silicon oxide becomes impractical to compensate for the poor conformality because the protrusion of deposited silicon oxide at the top of the feature opening can be limited by the width of the via opening. For small via widths, poor conformality can lead to closure of the opening at the top of the vias.

In general, a measure of conformality for a thin film provides a means for comparison between types of deposited films and the methods for depositing these films. At 100% conformality, a film is said to have the same thickness at all locations in and around the structure on which the film thickness is measured for comparison. CVD parylene processes can produce films that are nearly 100% conformal in typical TSV structures and in structures with aspect ratios of 40:1, and higher. Such high levels of conformality do not require excessive film thicknesses to be deposited at the top of the via to ensure adequate thickness at the bottom of the sidewall in comparison to films with poorer conformality. The resulting profile with a conformal film such as parylene has little or no difference in thickness between the tops and bottoms of features 40, so that the achievement of adequate coverage of the parylene with subsequent barrier and seed layer deposition processes, is greatly simplified.

Conformality is typically described as a percentage determined by the ratio of the minimum thickness to the maximum thickness of the same layer, or a stack of layers, on a structure. At a conformality of less than 100%, the deposited film thickness is not the same everywhere on the structure, where a structure can be a surface, a feature, a combination of features, or an entire substrate filled with a multitude of features.

In the inventive process, a specific level of conformality is not a prerequisite.

In the context of the inventive process 102, the conformality of the film need not be 100%, or approximately 100%. A conformality of 100% is defined as the condition in which the thickness of a film, or stack of films at the minimum thickness in etched structure 40 is equivalent in thickness to the same film, or stack of films, at the maximum thickness in the same etched structure 40. Some deviation from 100% conformality is, in practice, more typical than films deposited with 100% conformality.

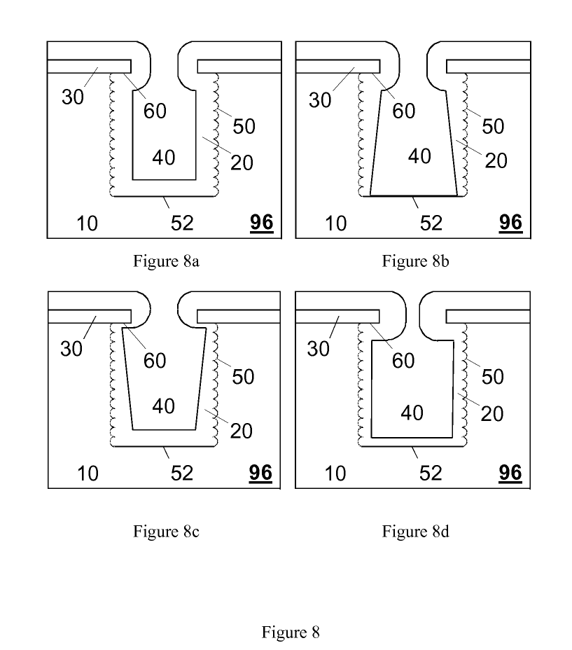

Some variations in conformality that might be observed in a process for depositing insulating films 20 that are compatible with the inventive process are provided in FIG. 8a to FIG. 8d.

In FIG. 8a, a highly conformal insulating film 20 is shown in etched structure 40. In the example shown in FIG. 8a, the film thickness is approximately the same everywhere in structure 40 shown (note: the differences in film thickness attributable to the scallops is not taken into consideration.) Deposited films 20 can have lower conformality, and in some cases significantly lower conformality, than shown in FIG. 8a and yet provide an acceptable level of conformality for the purpose of implementing the inventive process.

Some potential variations in coverage of film 20 with lower conformality than that shown in FIG. 8a, are shown in FIG. 8b, FIG. 8c, and FIG. 8d. These figures show examples of low, yet acceptable, levels of conformality for implementing the inventive process.

An acceptable level of conformality for the purposes of implementing the inventive processes requires only that the sidewall 50 is coated to at least a thickness sufficient to provide a continuous coating of the insulating film 20 on the sidewalls 50. The thickness of the coating 20 is subject to other design constraints that should be taken into consideration. The thickness of the insulating film does not need to be continuous on the horizontal surface 52 at the bottom of the feature 40 and on insulating surfaces, namely, the underside of mask layer 30 within etch structure 40 and parts of the sidewall that are electrically non-conductive.

In FIG. 8b, little or no deposition is shown on the horizontal surface at the bottom of etched feature 40, yet the sidewall 50 is covered. The insulating layer 20, however, decreases in thickness with increasing depth into the film structure 40. In this example shown in FIG. 8b, the minimum thickness of insulating film 20 on vertical sidewall 50 is closest to the bottom of etch structure 40, and, therefore, the minimum thickness at this point must be sufficient to provide a continuous film in this region. The deposited film must also be continuous in other areas of the sidewall where the insulating film is presumably thicker. In terms of conformality, the film must have sufficient conformality to produce the required minimal thickness of insulating layer 20 to produce continuous films on the sidewalls 50.

In the example shown in FIG. 8b, the film 20 on the horizontal surface 52 at the bottom of the etched structure 40 is generally removed in subsequent processing steps. In many proposed process flows for TSV fabrication, the substrate material that lies at, and below the horizontal plane of the horizontal surface 52 at the bottom of the etched structure 40, as oriented in FIG. 8a to FIG. 8d, is removed in subsequent processing steps as shown in FIG. 4.

In some cases, some substrate material is removed that lies above the horizontal plane of the horizontal surface 52 at the bottom of the etched structure 40. In embodiments in which material above the plane of the horizontal surface of the bottom of etched structure 40 is removed, the minimal acceptable conformality will provide at least a minimum thickness of insulating film 20 on vertical sidewall 50 to provide a continuous film at the depth into the substrate corresponding to the lowest point along sidewall 50 at which the insulating film lies between a conductive plug and the substrate 10.

In FIG. 8c, an embodiment is shown in which the thinnest coverage of the insulation layer 20 on sidewall 50 is in proximity to mask layer 30 near the top of the sidewall 50 for a structure that is oriented as shown in FIG. 8c. The minimal thickness of insulating layer 20 near the top of sidewall 50 must therefore be sufficient to form a continuous layer near the top of the sidewall 50. The underside of mask layer 30, as oriented in the FIG. 8c, does not require a continuous layer of insulator film 20.

In FIG. 8d, an embodiment is shown in which the insulating film 20 is much thinner within the feature 40 in comparison to the film on the top surface of mask layer 30, as oriented in FIG. 8d. In this embodiment, the thickness of film 20 must be sufficient to provide a continuous sidewall coating within the etched feature 40.

In applications in which an electric field is applied between the conductive plug 72, as in TSV applications, and the substrate 10, a continuous film may not be adequate to prevent failure of the insulation layer 20 during operation a the device. The requirement of the continuous film is provided as a definition of required conformality in applications of the inventive process.

In embodiments in which insulating substrates 10 are used, or multilayered substrates 10 with one or more insulating layers, the required thickness of film 20 may be significantly less than with conductive and semiconductive substrates 10. In some embodiments, in which insulating substrates are used, or multi-layered substrates 10 with one or more insulating layers, layer 20 may not need to cover portions of the etch structure corresponding to the insulating substrate, and may not need to be continuous within etched feature 40.

Deposition Techniques

In the preferred embodiment of the inventive process, conformal insulating layer 20 is parylene and is deposited using chemical vapor deposition.

In another embodiment, conformal insulating layer 20 is a polymer and is deposited using chemical vapor deposition In another embodiment, conformal insulating layer 20 is a polymer and is deposited using plasma enhanced chemical vapor deposition.

In another embodiment, conformal insulating layer 20 is a polymer deposited using an electrochemical-based deposition process.

In another embodiment, conformal insulating layer 20 is deposited using atomic layer deposition. In another embodiment, conformal insulating layer 20 is deposited using nanolayer deposition. In another embodiment, conformal insulating layer 20 is deposited using a process with alternating precursor deposition steps and treatment steps to incrementally create a required thickness of conformal insulating layer 20. In another embodiment, conformal insulating layer 20 is deposited using a spin-on deposition technique. In another embodiment, conformal insulating layer 20 is deposited using physical vapor deposition.

In another embodiment, conformal insulating layer 20 is deposited using at least one of chemical vapor deposition, plasma enhanced chemical vapor deposition, physical vapor deposition, electrochemical-based deposition, atomic layer deposition, nanolayer deposition, spin-on deposition, and a deposition process with alternating deposition steps, to deposit an incremental thickness of precursor material, and treatment steps, to convert the deposited precursor film to the intended film.

In another embodiment, conformal insulating layer 20 comprises one or more layers deposited by at least one of chemical vapor deposition, plasma enhanced chemical vapor deposition, physical vapor deposition, electrochemical-based deposition, atomic layer deposition, nanolayer deposition, spin-on deposition, and a cyclic deposition process with alternating deposition steps and treatment steps, to deposit an incremental thickness of precursor material and to convert the deposited precursor film to a suitable conformal insulating layer 20.

In another embodiment, conformal insulating layer 20 is a laminate of one or more insulating layers deposited by at least one of chemical vapor deposition, plasma enhanced chemical vapor deposition, physical vapor deposition, electrochemical-based deposition, atomic layer deposition, nanolayer deposition, spin-on deposition, and a cyclic deposition process with alternating deposition steps and treatment steps, to deposit an incremental thickness of precursor material and to convert the deposited precursor film to a suitable conformal insulating layer 20

In another embodiment, conformal layer 20 comprises one or more films, at least one of which is insulating.

In another embodiment, conformal layer 20 comprises one or more films, at least one of which is insulating, that are deposited by at least one of chemical vapor deposition, plasma enhanced chemical vapor deposition, physical vapor deposition, electrochemical-based deposition, atomic layer deposition, nanolayer deposition, spin-on deposition, and a cyclic deposition process with alternating deposition and treatment steps.

In another embodiment, conformal layer 20 is a composite of one or more co-deposited polymer materials that are deposited by at least one of chemical vapor deposition, plasma enhanced chemical vapor deposition, physical vapor deposition, electrochemical-based deposition, atomic layer deposition, nanolayer deposition, spin-on deposition, and a cyclic deposition process with alternating deposition and treatment steps.

In yet another embodiment, conformal layer 20 is a conformal polymer and a layer of one or more of silicon oxide and silicon nitride deposited by at least one of chemical vapor deposition, plasma enhanced chemical vapor deposition, physical vapor deposition, electrochemical-based deposition, atomic layer deposition, nanolayer deposition, spin-on deposition, and a cyclic deposition process with alternating deposition and treatment steps.

Methods for depositing films are known in the art and other methods that are used to deposit the conformal layer 20 are within the scope of the current invention.

Anisotropic Etch Process

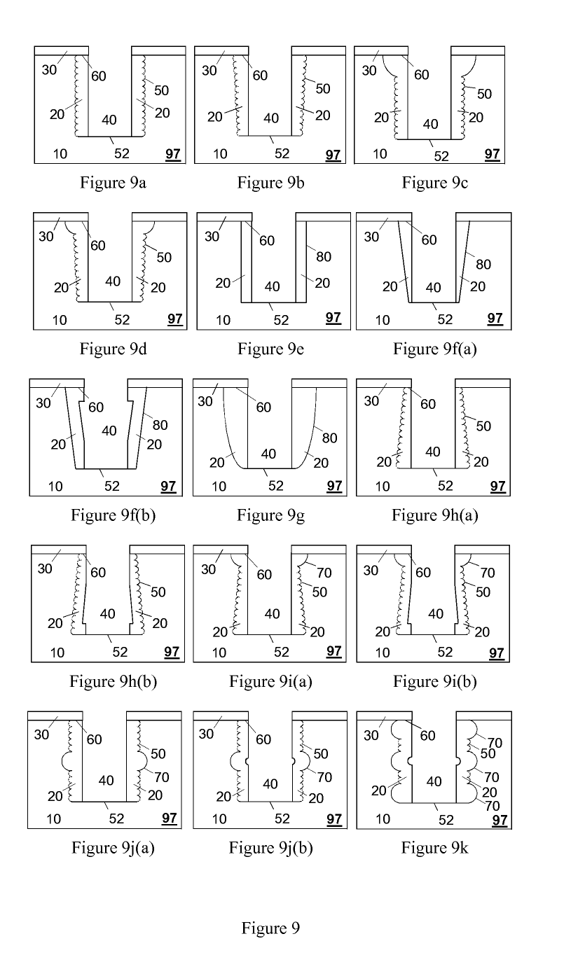

Step 150 of the inventive process shown in FIG. 5 is an anisotropic etch process used to remove portions of the insulating layer 20 from unmasked areas. In FIG. 9a to FIG. 9k, etched features are shown after exposure to anisotropic etch process 150. The figures shown in FIG. 9a to FIG. 9k correspond to the figures in FIG. 7a to FIG. 7k with the same suffix. For example, FIG. 7a shows feature 40 after conformal film deposition step 140 to deposit insulator layer 20 and FIG. 9a shows the corresponding feature after isotropic etch step 150. Similarly, FIG. 7b shows feature 40 after conformal film deposition step 140 to deposit insulator layer 20 and FIG. 9b shows the corresponding feature after isotropic etch step 150. FIG. 9c through FIG. 9k also show how the features shown in FIG. 7c through FIG. 7k might look after exposure to anisotropic etch step 150.

In the preferred embodiment, the features 40 with insulator layer 20 are exposed to an anisotropic etch process 150 using an oxygen-containing plasma to remove a conformal parylene layer 20 from areas of the structure in which the parylene coating 20 have a direct line of sight to the plasma. The use of the anisotropic etch process preferably restricts the removal of the conformal parylene coating to those surfaces that are unmasked, or unprotected from normally incident ions from a plasma.

In FIG. 9a to FIG. 9k, examples of etched structures formed using the inventive process are shown. In FIG. 9a, an embodiment is shown after exposure of the structure shown in FIG. 7a to etch process 150 in which the insulating layer 20 has been removed from areas of the structure in which the insulating layer 20 is exposed to the anisotropic plasma. In the embodiment shown in FIG. 9a, the etch process 150 removes insulating layer 20 from the top horizontal surface of mask layer 30, from the edges of the mask within the opening of mask layer 30, and from the horizontal surface at the bottom of etched feature 40. Additionally, some exposed insulating material 20 along the sidewalls of etched feature 40 may be intentionally or unintentionally removed although the conditions for the anisotropic etch 150 could be selected to limit the lateral etch rate. Alternatively, etch process 110 can be selected with conditions that produce a larger overhang 60 to reduce or minimize unintentional loss from insulator layer 20 on sidewall 50. Alternatively, a thicker layer of insulating layer 20 can be deposited to compensate for intentional or unintentional loss of insulating layer 20 on sidewall 50.

For some high aspect ratio etched features 40, the etch rate for the insulating layer 20 at the horizontal surface at the bottom of etched feature 40 can be lower than the etch rate for the insulating layer 20 on mask layer 30 outside of the etch feature 40. In another embodiment, etch process 150 removes insulating layer 20 from the top horizontal surface of mask layer 30 and from the edges of the mask within the opening of mask layer 30. In this embodiment, the insulating material 20 on the horizontal surface 52 at the bottom of etched feature 40 is either not etched or is only partially etched with etchback process 150.

Other embodiments are shown in FIG. 9b to FIG. 9k that similarly demonstrate the effect of etch step 150 on a variety of etched structures 40. The embodiments shown in FIG. 9a to FIG. 9k are intended to provide a sample of various shapes, various sidewall profile angles, various degrees of scalloping and surface roughness, and various means for anchoring materials deposited within one or more etched structures 40. Other shapes, profile angles, degrees of scalloping and surface roughness, and means for anchoring materials deposited within etched structures 40 can be used and remain within the scope of the present invention. Similarly, combinations of shapes, profile angles, degrees of scalloping and surface roughness, and means for anchoring materials can be used and remain within the scope of the present invention.

In the preferred embodiment, conformal parylene film 20 is removed with a plasma etch process 150, that is comprised of oxygen. In other embodiments of the inventive process, the conformal coating 20 is removed with a plasma etch process 150, that is comprised of oxygen and at least one of nitrogen, CO, CO₂, an inert gas such as helium, argon, neon, or xenon, a reactive gas such as hydrogen, methane, ammonia, and a reactive halogen containing gas such as fluorine (for example SF₆, CF₄, CHF₃, C₄F₆, C₂F₆, SiF₄, NF₃), chlorine (for example, Cl₂, CCl₂, SiCl₄BCl₃), and bromine (HBr, Br₂). A significant benefit of the inventive process is that no further masking of the substrate is required to selectively remove the parylene from areas in which it is not required for subsequent processing or in the final device structure.

In the preferred embodiment of the inventive process, the plasma exposure for removing the parylene from areas where it is not required can immediately follow the parylene deposition, preferably, within the same process module used to deposit the parylene, although removal in the same module is not required. A benefit of performing the etchback of the parylene in the same deposition module is that the plasma exposure used to perform the etch can simultaneously be used to remove unwanted material on chamber parts surrounding the wafer on which the parylene is likely to have deposited.

Etchback process 150 can be completed in-situ, in a separate standalone etch tool such as the 901 series etch tool manufactured by Tegal Corporation, or in an attached module in a cluster tool such as the 6500 series or Compact-series tools manufactured by Tegal Corporation of Petaluma, Calif. In general, higher etch rates can be achieved under etch process conditions that produce high bias powers or bias voltages on the substrate 300. Polymers, such as parylene, also tend to etch more quickly in high density plasmas. In one embodiment of the present invention, a multi-frequency configuration is used for the etch step 150 in which one or more frequencies are used to generate a high density plasma, and one or more frequencies are used to generate a bias on the substrate. Source configurations for plasma generation can be capacitive, inductive, or microwave. Downstream plasma sources can also be connected to process module 200 to produce higher etch rates for parylene and other polymeric insulating layers.

Although configurations that produce high plasma densities will ultimately lead to higher etch rates and higher throughput, the preferred embodiment shown in FIG. 3 has been shown to produce parylene etch rates of greater than 400 nm/min with rf power delivered from rf power generator 290 delivered through matching network 280 to electrode 310 at a frequency of 13.56 MHz. In the preferred embodiment, an oxygen plasma is used in the pressure range of 1-5000 mT, and more preferably 50-500 mT to remove a conformal parylene film 20. Increased parylene etch rates are achievable with higher power levels. Other frequencies of rf power can also be used in the range of 0.1 to 100 MHz to remove the conformal layer 20. Magnetic confinement with permanent magnets positioned within or near the chamber walls, and in some cases in the wall or electrode above the substrate 300, can also be used to increase the plasma density and to produce higher etch rates for the insulating layer 20.

In the preferred embodiment shown in FIG. 3, oxygen gas is provided to process chamber 200 through gas inlet 270 during etch process 150. Gas is evacuated from the process chamber 200 through throttle valve or orifice 330 and optional cold trap 340, and through vacuum line 350 to roughing pump 360. Flow rates for oxygen are in the range of 10 to 3000 sccm. In general, higher oxygen flows produce higher etch rates for polymeric films. Achievable flow rates are generally limited by other considerations such as the cost of the pumping system. Some photoresist strip modules, for example, use oxygen flow rates of 2000-3000 sccm to maximize removal rates of photoresist films. Parylene and other polymeric films tend to exhibit similar trends in etch rate behavior to that of photoresist, although at lower overall etch rates.

In FIG. 9a to FIG. 9k, etched structures 40 are shown after the parylene etchback process 150 has been used to remove the parylene from areas in which it is not required for subsequent processing. In embodiments in which the etched structures 40 are vias, the structure after etch process 150 show cylindrically-shaped sidewalls with insulating layers 20, namely parylene in the preferred embodiments, remaining on the scalloped, cylindrical sidewalls 50. In these preferred embodiment, the parylene that had been deposited on the horizontal surfaces outside of the via 40 on the top surface of the mask layer 30, and at the bottom of the via 40 has been removed. The parylene that had been deposited at the edge of the hard mask that had reduced the size of the opening at the top of the via has also been removed. In structures in which the mask layer 30 is a layer that is not susceptible to removal by the plasma chemistry used in the etchback process, such as for example, silicon dioxide, silicon nitride, other oxides or nitrides, or a combination of various layers including insulating films, semiconductor films, metal films, or combinations of these types of films, the size of the opening will not be affected, or will be minimally affected by the plasma exposure. The dimensions of the opening in the mask layer 30 will not be changed significantly for a mask material that is not significantly etched by the chemistry of the etchback process. Mask layer 30 can be used to ensure that parylene on the sidewalls of the vias 40 is protected during anisotropic etchback process 150. The remaining mask layer will also ensure that the parylene at the top of the via 40 is protected from direct impingement from ions from the anisotropic plasma that, in the absence of the overhang 60 in hard mask 30, could otherwise remove parylene from the top of the via that could potentially lead to shorting between the substrate 10 and the conductive plugs that are deposited in subsequent processing steps.

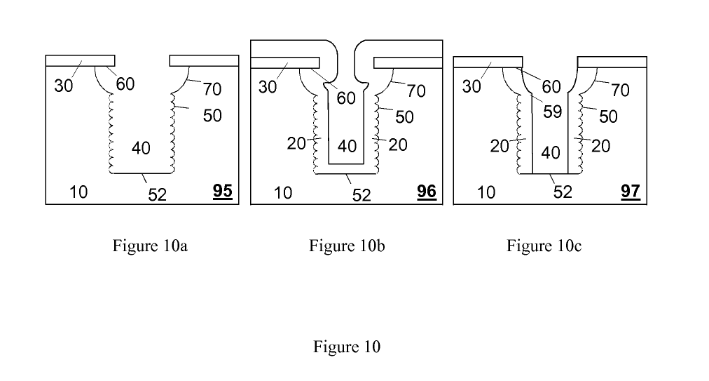

In FIG. 10a to FIG. 10c, a preferred embodiment is shown. In FIG. 10a, sidewall 50 is approximately aligned with opening in mask layer 30 of etched structure 40 and large scallop 70 is shown to provide overhang 60. In FIG. 10b of this preferred embodiment, conformal insulating layer 20 is shown to mostly fill large scallop 70. In FIG. 10c, the preferred embodiment is shown after anisotropic etch 150 in which the conformal insulator layer has been removed from the top surface of mask layer 30, from within the opening of mask layer 30, and from a portion of the structure below the mask layer 30 within etch structure 40. The removal of the insulator layer 20 with anisotropic etch process 150 below mask layer 30 produces a favorable structure for subsequent filling and coating processes. Conformal layer 20 is removed from within the opening in mask layer 30 and below to the extent that any material that may have produced a shadowing effect in subsequent filling and coating processes has been eliminated. The shoulder 59 shown in FIG. 10c is applicable to other embodiments of the inventive process and in particular to those in which the sidewall insulator 20 extends laterally beyond the opening in mask layer 30 within etched structure 40. Other embodiments in which the insulator layer extends into the opening in mask layer 30 are possible and within the scope of the present invention.

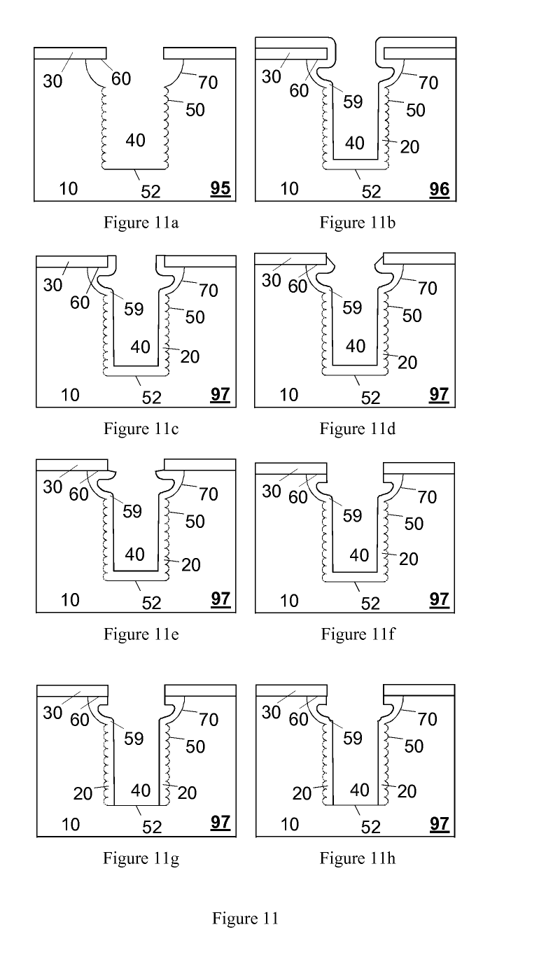

In FIG. 11, a number of images are shown for reference and a number of images are shown with variations of the anisotropic etch process 150 that are within the scope of the present invention. FIG. 11a and FIG. 11b are structures 95 and 96 after etch process 110 and deposition step 140, respectively, and are provided for reference. The embodiment of structure 96 shown in FIG. 11b shows large scallop 70, partially filled with conformal insulator 20 leaving a recess that could be used to provide a means for mechanical anchoring of fill material. The embodiments shown in FIG. 11c to FIG. 11h provide some examples of the potential variations in the anisotropic etch step 150.

In FIG. 11c, structure 97 is shown after anisotropic etch step 150 in which the portion of the conformal insulator layer above the mask layer 30 is removed. In FIG. 11d, structure 97 is shown in which the conformal layer above the mask 30 and a portion of the conformal layer 20 from within the opening of mask layer 30 have been removed with anisotropic etch process 150. In FIG. 11e, structure 97 is shown in which the conformal layer 20 above the mask 30 and from within the mask layer have been removed with anisotropic etch process 150. In FIG. 11f, structure 97 is shown in which the conformal layer 20 above the mask layer 30, the conformal layer 20 from within the opening in mask layer 30, and a portion of the mask layer from below the mask layer 30 have been removed with anisotropic etch process 150. In FIG. 11g, structure 97 is shown in which the conformal layer 20 above the mask layer 30, the conformal layer 20 from within the opening in mask layer 30, a portion of the mask layer from below the mask layer 30, and the conformal layer 20 on the horizontal surface 52 at the bottom of etch structure 40 have been removed with anisotropic etch process 150. Some removal of material from the shoulder 59 in FIG. 11g is likely to occur in some structures, and in particular, some structures in which the shoulder has a direct line of sight to the plasma used to provide the anisotropic etch process 150. In FIG. 11h, structure 97 is shown in which the conformal layer 20 above the mask layer 30, the conformal layer 20 from within the opening in mask layer 30, a portion of the mask layer from below the mask layer 30, and the conformal layer 20 on the horizontal surface 52 at the bottom of etch structure 40 have been removed with anisotropic etch process 150 along with a portion of conformal layer 20 from the shoulder 59.

Mechanical Anchoring Mechanisms for Conductive Plugs

In FIG. 9f(b), FIG. 8h(b), FIG. 9i(b), and FIG. 9j(b), a means for providing mechanical anchoring for conductive plugs that are deposited over insulating layer 20 is shown. The recesses 55 created in the sidewalls of these embodiments provide a means for preventing movement of filler materials, such as the conductive plugs used in through silicon vias, upon exposure of completed device structures to conditions that could cause such movement.

Back-end fabrication steps used in the manufacturing of devices often expose device structures to temperatures as high as 450° C., for example, in anneals for alloying metal contacts. Also, chemical vapor deposited barrier layers and seed layers can reach temperatures of 300° C., or higher.

Devices, such as microprocessors, can generate significant amounts of heat during operation in end products that can also expose co-packaged devices to wide ranges of temperature.

These temperature variations can create stresses in embodiments such as the structure shown in FIG. 4, for example, that can potentially lead to slippage at the interfaces between the insulating layer 20 and the film or films that cover the insulator layer. In applications in which large variations exist in one or more of the temperature coefficients of expansion between the substrate, the insulator, and the metal layers that cover the insulator, a means for mechanically anchoring the layers that cover insulating layer 20 can be beneficial.

In FIG. 9f(b), FIG. 9h(b), and FIG. 9i(b), a means for providing a mechanical anchoring mechanism is produced with recesses 55 in insulating layer 20 after etchback process 150. The embodiments in FIG. 9f(b), FIG. 9h(b), and FIG. 9i(b) show structures in which mechanical anchoring can be achieved through a combination of providing a particular shape to the via structure 40 in which the sidewall 50 has a non-vertical profile, and providing a lateral depth relative to the edge of the mask layer 30 in the opening of the etched feature 40, that is greater than the thickness of the deposited insulation layer 20.

In FIG. 9j(b) and FIG. 9k, a means for providing a mechanical anchoring mechanism is produced by introducing large scallops 70 into sidewall 50 during etch process 110. These large scallops 70 can be used to produce the recess in insulating layer 20, relative to the edges of mask layer 30 in the openings at the top of etched structures 40, after deposition step 140 as shown in FIG. 9j(b). The embodiment in FIG. 9j(b) shows a structure in which mechanical anchoring can be achieved through a combination of providing a shape to the via structure 40 in which the sidewall has a vertical or near-vertical profile, and providing a lateral depth of large scallop 70, relative to the edge of the mask layer 30 in the opening of the etched feature 40, that is greater than the thickness of the deposited insulation layer 20.

The recess in the insulating layer 20, corresponding to the large scallop 70 in sidewall 50, provides a means for mechanically anchoring fill materials to the insulator layer 20 that are deposited after the insulator deposition step 140 and etchback step 150. The mechanical anchoring mechanism produced by the recess in sidewall insulator 20 can favorably distribute stresses between insulator 20 and materials that are deposited in subsequent deposition steps, after etchback 150, to eliminate interfacial slippage that might occur in applications in which large variations exist in one or more of the temperature coefficients of the substrate and the films deposited within structure 97, for example, and in which the structures are subjected to variations in temperature.

The large scallop 70 in FIG. 9j(b), is shown as having a cross section that is semicircular. Other cross sections can also be produced in which at least one pronounced recess is formed that extends laterally beyond the primary trajectory of the profile of sidewall 50 in substrate 10 to provide a means for mechanically anchoring the materials that are deposited into etch feature 40 after the anisotropic etch step 150 and be within the scope of the present invention. Similarly, lateral projections that extend inward into etch structure 40 to provide a means for mechanically anchoring the fill materials is also within the scope of the current invention.

Recesses 55 that are created in the sidewalls of etched structures 40, after deposition of the insulator layer 20, can also provide a means for mechanically anchoring layers or fill materials that are subsequently deposited within etched structure 40 after the insulator layer 20. This means for mechanically anchoring can favorably distribute stresses in applications in which adhesion between the subsequently deposited materials and the insulator layer 20 is insufficient to prevent slippage when the structures are exposed to variations in temperature.

Recesses 55 that are created in the sidewalls of etched structures 40, after deposition of the insulator layer 20 can also provide a means for mechanically anchoring layers or fill materials that are subsequently deposited within etched structure 40 after the insulator layer 20. This means for mechanically anchoring can favorably distribute stresses in applications in which the film properties of the conformal insulation layer 20 or a layer that is deposited over layer 20 in subsequent process steps are modified as a result of the exposure to subsequent processing steps, to changes in ambient conditions, or to changes from operation of the devices. These changes might occur as a result of an exposure to a change in temperature, for example. Examples of some film properties that might be changed are density and crystal structure.

The examples of compensating for variations in the temperature coefficients of materials, for poor adhesion, and for changes in film properties are provided for example only. Other reasons might exist for which an embodiment with sidewall recesses as a means for mechanically anchoring fill materials in etch structure 40 to insulator layer 20 are preferable over other embodiments and be within the scope of the current invention.

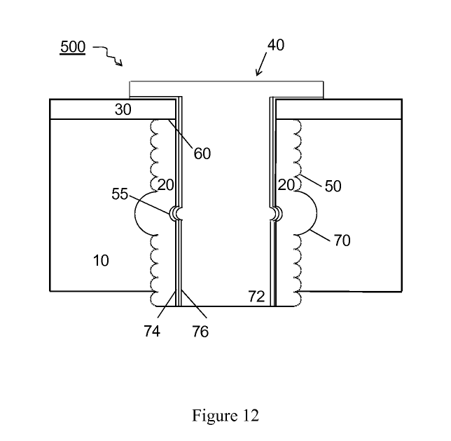

In FIG. 12, a through-silicon-via is shown in which barrier and seed layers have been deposited over insulator layer 20, in which a conductive plug is deposited over the seed layer, and part of the substrate has been removed. The image shown in FIG. 12 is representative of a completed via structure 40 that can be used to connect devices at the top of substrate 10 to other substrates or devices positioned below substrate 10 through the conductive plug. In this example, etched structure 40 is a via. Mask structure 30 is shown with overhang 60. Mechanical anchoring means is provided in sidewall 50 to anchor insulating layer 20 to substrate 10, and to anchor conductive plug 72 to the insulating layer 20.

What is claimed is:

1. A method of forming a structure on a substrate, comprising:
a. etching a via or trench pattern on the substrate, the via or trench pattern comprising an overhang on a sidewall; and
b. depositing a dielectric layer coating the sidewall and a portion of the underside of the overhang.

2. A method as in claim 1 further comprising forming a mask pattern on the substrate before etching the via or trench pattern.

3. A method as in claim 1 wherein the etching process comprises an isotropic etch for forming the overhang.

4. A method as in claim 1 wherein the etch process comprises at least one of a plasma etch, a laser etch, a wet etch, ion milling, and reactive ion milling.

5. A method as in claim 1 wherein the dielectric layer forms a conformal layer coating the overhang and the sidewall.

6. A method as in claim 1 wherein the dielectric layer provides a sidewall with smoother surface than the sidewall surface after etching.

7. A method comprising:
a. providing a substrate having a via or trench pattern comprising an overhang on a sidewall;
b. depositing a dielectric layer coating the sidewall and a portion of the underside of the overhang; and
c. anisotropically etching the dielectric layer.

8. A method as in claim 7 wherein the overhang is formed from a mask layer and an isotropic etch process.

9. A method as in claim 7 wherein the dielectric layer forms a conformal layer coating the overhang and the sidewall.

10. A method as in claim 9 wherein the overhang blocks the anisotropic etch from removing the portion of the dielectric layer coating the sidewall.

11. A method as in claim 7 wherein the dielectric layer deposition process comprises at least one of a chemical vapor deposition, electrochemical deposition, plasma enhanced chemical vapor deposition, atomic layer deposition, nanolayer deposition, spin on deposition, and physical vapor deposition

12. A method as in claim 7 wherein the dielectric layer comprises a parylene layer.

13. A method as in claim 7 further comprising depositing a silicon dioxide layer before depositing the dielectric layer.

14. A method as in claim 7 wherein the anisotropic etch removes the dielectric layer at a top surface of the via or trench pattern.

15. A method as in claim 7 wherein the overhang is formed from a mask layer and wherein the anisotropic etch removes the dielectric layer at a top surface of the via or trench pattern and a portion of the dielectric layer coating the sidewall of the mask layer.

16. A method as in claim 7 wherein the overhang is formed from a mask layer and wherein the anisotropic etch removes the dielectric layer coating the sidewall of the mask layer.

17. A method as in claim 7 wherein the overhang is formed from a mask layer and wherein the anisotropic etch removes the dielectric layer within and a portion below the mask opening.

18. A method as in claim 7 wherein the anisotropic etch removes the dielectric layer at a top surface and a portion or all at a bottom surface of the via or trench pattern.

19. A method as in claim 7 wherein the overhang is formed from a mask layer and wherein the anisotropic etch removes the dielectric layer at a top surface of the via or trench pattern, the dielectric layer coating the sidewall of the mask layer, and the dielectric layer at a bottom surface of the via or trench pattern.

20. A method as in claim 7 wherein the overhang is formed from a mask layer and wherein the anisotropic etch removes the dielectric layer at a top surface of the via or trench pattern, the dielectric layer coating the sidewall of the mask layer, a portion of the dielectric layer below the mask opening, and the dielectric layer at a bottom surface of the via or trench pattern.

21. A method as in claim 7 wherein the via or trench pattern comprises an anchor on the sidewall, acting as an anchor for a subsequently deposited film.

22. A method as in claim 21 wherein the anchor comprises one of a scalloped wall, a shape of the via or trench, and a recess on a sidewall.

23. A method of forming through-silicon interconnects in a silicon substrate, comprising:
a. patterning a mask layer on the silicon substrate;
b. etching the silicon substrate to form at least a via or trench structure with the mask layer forming an overhang on a sidewall of the via or trench structure;
c. depositing a parylene dielectric layer coating the sidewall and a portion of the underside of the overhang;
d. anisotropically etching the parylene dielectric layer from areas not protected by the overhang; and
e. depositing a conducting interconnect film.

24. A method as in claim 23 wherein the mask layer comprises at least one of a hard mask and a photoresist mask.

25. A method as in claim 23 wherein etching the silicon substrate comprises an alternating etching and passivating process.

26. A method as in claim 23 wherein the alternating etching and passivating process forms a scalloped sidewall.

27. A method as in claim 23 wherein the parylene dielectric layer provides a sidewall with smoother surface than the sidewall surface after etching.

28. A method as in claim 23 further comprising depositing a silicon dioxide layer before depositing the parylene dielectric layer.

29. A method as in claim 23 further comprising depositing an adhesion layer before depositing the parylene dielectric layer.

30. A method as in claim 23 wherein the anisotropic etch removes the parylene dielectric layer at a top surface of the via or trench pattern.

31. A method as in claim 23 wherein the anisotropic etch removes the parylene dielectric layer at a top surface of the via or trench pattern and a portion of the dielectric layer coating the sidewall of the mask layer.

32. A method as in claim 23 wherein the anisotropic etch removes the parylene dielectric layer coating the sidewall of the mask layer.

33. A method as in claim 23 wherein the anisotropic etch removes the parylene dielectric layer anisotropically within and below the mask opening.

34. A method as in claim 23 wherein the anisotropic etch removes the parylene dielectric layer at a top surface and a portion or all at a bottom surface of the via or trench pattern.

35. A method as in claim 23 wherein the anisotropic etch removes the parylene dielectric layer at a top surface of the via or trench pattern, the dielectric layer coating the sidewall of the mask layer, and the dielectric layer at a bottom surface of the via or trench pattern.

36. A method as in claim 23 further comprising depositing a barrier layer before depositing the conducting interconnect film.

37. A method as in claim 23 further comprising depositing a seed layer before depositing the conducting interconnect film.

38. A method as in claim 23 wherein etching the silicon substrate forms an anchor on the sidewall.

39. A method as in claim 23 wherein the parylene layer forms an anchor on the sidewall, acting as an anchor for the conducting interconnect film.

40. A method as in claim 39 wherein the anchor comprises one of a scalloped wall, a shape of the via or trench, and a recess on a sidewall.
